(19) United States
(12) Patent Application Publication
(10) Pub. No.: US 2025/0209235 A1
(43) Pub. Date: Jun. 26, 2025

(54) SYSTEM CONFIGURATION DERIVATION DEVICE, SYSTEM CONFIGURATION DERIVATION METHOD, AND STORAGE MEDIUM

(71) Applicant: NEC Corporation, Tokyo (JP)

(72) Inventors: Takuya KUWAHARA, Tokyo (JP); Toshiki WATANABE, Tokyo (JP); Takayuki KURODA, Tokyo (JP)

(73) Assignee: NEC Corporation, Tokyo (JP)

(21) Appl. No.: 18/976,540

(22) Filed: Dec. 11, 2024

(30) Foreign Application Priority Data
Dec. 20, 2023 (JP) 2023-215132

(51) Int. Cl. G06F 30/20

(52) U.S. Cl. CPC G06F 30/20

(57) ABSTRACT

A system configuration derivation device calculates a recovery cost required for recovery of a structure derived from an expected configuration of an entity having as a type a constituent component model based on information on a recovery model and the expected configuration; constructs a global state model representing an operation model relating to failure recovery of the abstract configuration; verifies whether the global state model satisfies the recovery time requirement; and generates an abstract configuration that embodies the functional requirement using a mechanism for gradually embodying the abstract configuration as a possible system configuration candidate, and derives a system configuration that simultaneously satisfies the functional requirement and the recovery time requirement by eliminating the candidates that do not satisfy the recovery time requirement.

This application is based upon and claims the benefit of priority from Japanese patent application No. 2023-215132, filed on Dec. 20, 2023, the disclosure of which is incorporated herein in its entirety by reference.

### TECHNICAL FIELD

The present disclosure relates to a system configuration derivation device, a system configuration derivation method, and a storage medium.

### BACKGROUND ART

In a case where constructing an Information and Communication Technology (ICT) system for the purpose of service operation, etc., system configuration design work is necessary. The design work of system configuration involves constructing the necessary system components and their connection relationships (hereinafter referred to collectively as the “system configuration”) to meet the requirements of the desired system (hereinafter referred to as “system requirements”) without any deficiencies. Furthermore, it is essential to accurately set all configuration parameters required for the entire system to operate correctly, and this can be a very labor-intensive task in some cases.

Automatic design technology is a technology that automates the above design process, i.e., the process of materializing system requirements into a system configuration. Although many existing automatic design technologies are based on restricting the problem to a specific domain of the ICT system, e.g., network routing or computation resource allocation, and then solving some kind of optimization problem, etc., for automatic design, research into techniques to meet generic requirement descriptions is ongoing.

For example, in T. Kuroda, Y. Yakuwa, K. Tanabe, “Network Design Automation Technology by AI/ML,” The Journal of the Institute of Electronics, Information, and Communication Engineers, vol. 105, no. 10, pp. 1208-1214, 2022 (hereinbelow referred to as Non-Patent Document 1), a technique is described for automatically deriving a system configuration based on functional requirements described using a generic system configuration information model in a graph-like format. According to the technology described in Non-Patent Document 1, automatic design is possible with generic and multifaceted requirements as input by preparing the necessary models.

The requirements that can be described by the generic model described in Non-Patent Document 1 are mainly specified by a graph-like representation in which functions, devices, and other components are represented as nodes, and the relationships among the nodes are represented by edges (oriented edges) (Hereinafter this is called an “abstract configuration”. However, in Non-Patent Document 1 it is referred to as a “dependent structure”.). For example, the requirement “Communication between two servers by Transmission Control Protocol (TCP) is possible” is expressed as an abstract configuration composed of nodes corresponding to each server connected by edges that express “TCP communication possible”. The method described in Non-Patent Document 1 is a mechanism for automatically deriving a way to embody the abstract “TCP communication possible” edges contained in the aforementioned abstract configuration. (Hereinafter, nodes and edges are collectively referred to as “entities.”)

It should be noted that the automatic design method described in Non-Patent Document 1 does not embody the given requirements at once. In the above-mentioned automated design technique, for each model data (hereafter referred to as a “component model”) that represents relevant information for an entity type (hereafter referred to as a “type”), peripheral configuration information (hereafter referred to as an “expected configuration”) necessary for an entity having that type to function properly as a system component is stored as data, and this is then sequentially applied to abstract configurations that represent requirements, or the types of nodes and edges are replaced with more specific types, thereby gradually converting the abstract configuration into a more specific one.

Here, “applying the expected configuration” refers to an operation performed on abstract nodes or edges (hereinafter referred to as “unit requirements”) included in the abstract configuration, and refers to adding a structure equivalent to the expected configuration to the abstract configuration for unit requirements that do not have an expected configuration.

In contrast to the “application of the expected configuration” operation, the operation of replacing an entity type with a more specific type is called “type refinement.” Operations that apply expected configurations to entities or refine types are collectively called “embodiment” operations.

The automated design method described in Non-Patent Document 1 can be said to be a method for repeatedly embodying input functional requirements, thereby obtaining an abstract configuration in which all unit requirements contained in the requirements are resolved. Furthermore, the abstract configuration thus obtained can be considered to be a completely embodied system configuration (hereinafter simply referred to as a “concrete configuration”) that does not contain any abstract elements.

In this manner, automatic design is possible by the gradually embodiment of functional requirements expressed in an abstract configuration.

The functional requirements handled in the automated design described above are primarily those items necessary for each component to operate normally with appropriate performance in line with the requirements, and these are merely requirements concerning the behavior of the system in a case where it is operating normally.

On the other hand, users of system automation design technology (hereafter referred to as “service operators”) often have requirements not only for the state in which the system is operating normally, but also for recovery from anticipated failures due to some kind of abnormality. Among these, one of the most common is the Recovery Time Objective, (hereafter referred to as “RTO”), such as “Can the system be restored to a normal state within one day?” or “Can the system be restored to an operational state within 10 minutes?” The RTO is expressed as a recovery state and an upper limit on the execution time of the procedure (recovery procedure) from the failure state to reach that state.

If the automated design can accurately reflect the RTO, it will be possible to design a system that operates a service with high resistance to failures through automated design.

In a case where attempting to reflect a RTO within the framework of existing automated design, one possible method is to remove an abstract configuration from valid configuration candidates in a case where it is determined that the abstract configuration in the process of being embodied does not satisfy the RTO. For example, in the technique described in Japanese Patent No. 2021-135625 (hereinbelow referred to as Patent Document 1), parameter-related constraints are added to an abstract configuration in a case where the abstract configuration is being embodied, and the embodiment of the abstract configuration is terminated in a case where a combination of parameter values that satisfies the constraints no longer exists, enabling the output of a system that satisfies quantitative constraints.

One possible method for determining the recovery procedures necessary to find the RTO is to describe the “behavior” of each part in a component model and embody it in parallel with the abstract configuration, thereby embodying not only the system configuration but also the operating model. In a case where considering a RTO, model data that defines “recovery operations from a failure” (hereinafter referred to as “recovery model”) is written in the component model. This is embodied during embodiment of the abstract configuration, and the recovery time can be found by determining the transition procedure from the failure state to the state to be recovered on the recovery model and calculating the execution time cost of that procedure.

One possible method is to apply a technique similar to that described in Patent Document 1 to reflect the RTO, thereby calculating the recovery time for an abstract configuration and checking whether this satisfies the RTO specified in the requirements. However, this approach has problems with computational efficiency.

An abstract configuration is a configuration in which part of the system is in an undetermined state, and in a case where a recovery procedure is calculated in this state, that part will inevitably be undetermined. Currently, there is no way to estimate the time required to execute the undetermined parts of the recovery procedure, and therefore there is no choice but to treat the undetermined parts as if they do not have any recovery time. In this case, the recovery time is the time required to execute the confirmed part of the recovery procedure (hereinafter referred to as the confirmed recovery time).

However, since the confirmed recovery time is inevitably estimated to be significantly lower than the final system recovery time, pruning using the upper limit hardly works in this method. Pruning using the confirmed recovery time only works for configurations that are obviously redundant and would take too long to recover, or for configurations where the difference between confirmed recovery time and actual recovery time has become small enough after most of the parts have been embodied.

This method is fine if the only requirement is to ensure that the final configuration satisfies the RTO, but in cases where the RTO is practically specified, it is considered that this method cannot obtain the desired configuration within a realistic time period. For example, in a case where it is necessary to prepare a specific additional configuration to satisfy the RTO (for example, in addition to a normal system that operates during normal operation, a standby system that operates temporarily in the event of a failure, etc.), a reasonable configuration will be searched for, including abstract configurations that include patterns that do not have such additional structures (to satisfy the RTO). However, in existing automated design, the search tends to prioritize configurations with the fewest number of elements within a range that satisfies the constraints. In the above case, it is not possible to arrive at an embodied configuration that correctly satisfies the RTO until all abstract configurations that do not contain the structure necessary to satisfy the RTO (and therefore cannot be a correct concrete configuration) have been explored. This requires embodying a huge number of abstract configurations before arriving at a correct concrete configuration that satisfies the RTO, and then verifying that the RTO is not satisfied.

One of the objects of the present disclosure is to provide a method for efficiently deriving configuration information of a system that simultaneously satisfies both functional requirements and recovery time requirements.

### SUMMARY

According to one example aspect of the present disclosure, a system configuration derivation device comprising: at least one memory configured to store instructions; and at least one processor configured to execute the instructions to: calculate, with a constituent component model as input, a recovery cost required for recovery of a structure derived from an expected configuration of an entity having a type indicated by the component model, based on information on a recovery model defined in association with the component model and the expected configuration, in a case where embodiment refers to a transformation of a graph structure that determines undecided parts of an abstract configuration based on information of the expected configuration, wherein the expected configuration is a peripheral structure necessary for system components to operate normally; the recovery model is model data that represents a relationship between failure recovery operations of the system components and the peripheral structures; the constituent component model is model data that defines type-specific information including the expected configuration and the recovery model of various abstract or concrete system components; the abstract configuration is a representation of a configuration of a system that includes undetermined parts, using a graph-like structure including nodes that correspond to components and edges that indicate relationships between the components; the entity includes the nodes and edges; construct, with the abstract configuration and the recovery cost as input, a global state model representing an operation model relating to failure recovery of the abstract configuration; verify, with the global state model and a recovery time requirement as input, whether the global state model satisfies the recovery time requirement; and generate, with a functional requirement and the recovery time requirement as input, the abstract configuration that embodies the functional requirement using a mechanism for gradually embodying the abstract configuration as a possible system configuration candidate, inputs the generated abstract configuration to the constructing to obtain the global state model, and inputs the global state model and the recovery time requirement to the verifying to eliminate candidates that do not satisfy the recovery time requirement, thereby deriving a system configuration that simultaneously satisfies the functional requirement and the recovery time requirement.

According to one example aspect of the present disclosure, a system configuration derivation method comprising: calculating, with a constituent component model as input, a recovery cost required for recovery of a structure derived from an expected configuration of an entity having a type indicated by the component model, based on information on a recovery model defined in association with the component model and the expected configuration, in a case where embodiment refers to a transformation of a graph structure that determines undecided parts of an abstract configuration based on information of the expected configuration, wherein the expected configuration is a peripheral structure necessary for system components to operate normally; the recovery model is model data that represents a relationship between failure recovery operations of the system components and the peripheral structures; the constituent component model is model data that defines type-specific information including the expected configuration and the recovery model of various abstract or concrete system components; the abstract configuration is a representation of a configuration of a system that includes undetermined parts, using a graph-like structure including nodes that correspond to components and edges that indicate relationships between the components; and the entity includes the nodes and edges; generating, with a functional requirement and a recovery time requirement as input, the abstract configuration that embodies the functional requirement using a mechanism for gradually embodying the abstract configuration as a possible system configuration candidate; constructing, with the generated abstract configuration and the recovery cost as input, a global state model representing an operation model relating to failure recovery of the abstract configuration; verifying, with the global state model and the recovery time requirement as input, whether the global state model satisfies the recovery time requirement; and deriving a system configuration that simultaneously satisfies the functional requirement and the recovery time requirement by eliminating the candidates that do not satisfy the recovery time requirement.

According to one example aspect of the present disclosure, there is provided a storage medium storing a program for causing a computer to execute the above-described processing.

### BRIEF DESCRIPTION OF THE DRAWINGS

FIG. 1 is a first block diagram showing a configuration example of a system configuration derivation device.

FIG. 2 is a first block diagram showing an example of the configuration of a dependent recovery cost calculation portion.

FIG. 3 is a flowchart illustrating an example of the operation of a configuration embodiment portion 101 in the system configuration derivation device.

FIG. 4 is a flowchart illustrating an example of the operation of a recovery model construction portion 103.

FIG. 5 is a flowchart illustrating an example of an operation of a recovery time requirement verification portion 104.

FIG. 6 is a flowchart illustrating an example of the operation of the dependent recovery cost calculation procedure control portion 200.

FIG. 7 is a flowchart illustrating an example of the operation of a tangible type-dependent recovery cost construction portion 201.

FIG. 8 is a flowchart illustrating an example of the operation of the intangible type-dependent recovery cost construction portion 202.

FIG. 9 is a flowchart illustrating an example of an operation of a dependent recovery cost integration portion 204.

FIG. 10 is a flowchart illustrating an example of the operation of the dependent recovery cost propagation portion 203.

FIG. 11 is a second block diagram showing a configuration example of the system configuration derivation device.

FIG. 12 is a flowchart illustrating an example of the operation of a recovery time requirement verification portion 1101.

FIG. 13 is an explanatory diagram showing an example of an expected configuration defined in a component part model.

FIG. 14 is an explanatory diagram showing a recovery state transition system.

FIG. 15 is an explanatory diagram showing a recovery state set.

FIG. 16 is an explanatory diagram showing an example of a recovery model for a tangible type.

FIG. 17 is an explanatory diagram showing an example of an expected configuration for an intangible type.

FIG. 18 is an explanatory diagram showing an example of a recovery model for an intangible type.

FIG. 19 is an explanatory diagram showing an example of an abstract configuration.

FIG. 20 is an explanatory diagram showing an example of an expected configuration having a structure larger than a single SELF node as a prerequisite configuration.

FIG. 21 is an explanatory diagram showing an example of a global state model corresponding to the abstract configuration shown in FIG. 19.

FIG. 22 is an explanatory diagram showing a state of embodiment that applies the expected configuration shown in FIG. 13 to the abstract configuration shown in FIG. 19.

FIG. 23 is an explanatory diagram illustrating two examples of a recovery procedure for recovering two applications A1 and A2 and the machines M1 and M2 that host them, respectively.

FIG. 24 is an explanatory diagram showing an example of a recovery model for explaining the operation of the tangible type-dependent recovery cost construction portion 201.

FIG. 25 is an explanatory diagram showing the node states of the target configuration required to execute the transitions SELF:F→A, SELF:A→C, and SELF:C→H in the recovery model, in order to explain the operation of the tangible type-dependent recovery cost construction portion 201.

FIG. 26 is an explanatory diagram showing an expected configuration and a recovery model assumed as a premise for explaining dependent recovery costs by way of example.

FIG. 27 is an explanatory diagram showing an example of a graph structure of a pattern group that the dependent recovery cost calculation procedure control portion 200 configures during its operation.

FIG. 28 is a conceptual diagram showing an example of a state transition system made up of global states and transitions between them.

FIG. 29 is an image diagram of the graph scanning process in FIG. 28 by the recovery time requirement verification portion 104.

FIG. 30 is an explanatory diagram showing an example of a result of application of the recovery model construction portion 103 to an abstract configuration having only one Target type node.

FIG. 31 is an explanatory diagram showing an example of a result of application of the recovery model construction portion 103 to an abstract configuration composed of one Target type node and one SubA type node.

FIG. 32 is a third block diagram showing an example of the configuration of a system configuration derivation device.

### EXAMPLE EMBODIMENT

Hereinbelow, a system configuration derivation device according to each example embodiment of the present disclosure will be described with reference to the drawings. The system configuration derivation device automatically generates a desired ICT system from system requirements (hereinafter referred to as “new requirements”) input by a user. The system configuration derivation device designs a system so that the recovery time from a failure is within a specified time. In the drawings used in the following description, the configuration of parts that are not related to the present disclosure may be omitted or not illustrated. In all drawings, the same or corresponding components are denoted by the same reference numerals, and common descriptions may be omitted.

### First Example Embodiment

### (Composition)

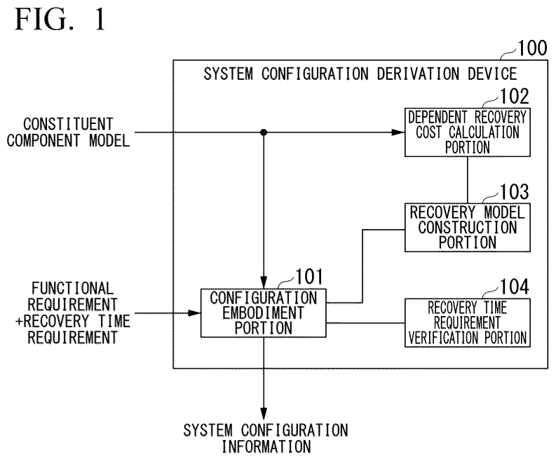

FIG. 1 is a first block diagram showing an example of the configuration of a system configuration derivation device 100. As shown in FIG. 1, the system configuration derivation device 100 is provided with a configuration embodiment portion 101, a dependent recovery cost calculation portion 102, a recovery model construction portion 103, and a recovery time requirement verification portion 104.

The configuration embodiment portion 101 receives as input an abstract configuration representing a system requirement, a recovery time requirement for the abstract configuration, and a component model required for embodying the system requirement, and derives a concrete configuration by gradually embodying the input abstract configuration.

The dependent recovery cost calculation portion 102 receives a type as an input, and calculates dependent recovery costs for each recovery task in a recovery model defined in each component model corresponding to the type.

The recovery model construction portion 103 receives an abstract configuration as an input, and calculates a global state model that corresponds to the abstract configuration and reflects the dependent recovery cost.

The recovery time requirement verification portion 104 receives the global state model and the recovery time requirement as input, and verifies whether the abstract configuration on which the global state model is based satisfies the recovery time requirement.

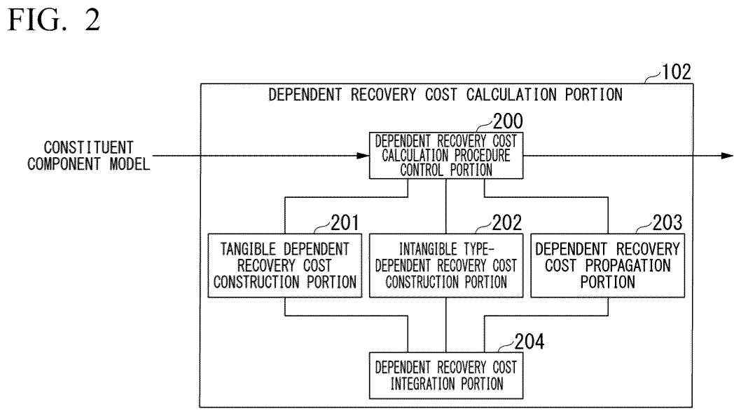

Moreover, the dependent recovery cost calculation portion 102 of the present example embodiment is provided with an auxiliary operation portion which is further subdivided. FIG. 2 is a block diagram showing an example of the configuration of the dependent recovery cost calculation portion 102.

The dependent recovery cost calculation portion 102 is provided with a dependent recovery cost calculation procedure control portion 200, a tangible dependent recovery cost construction portion 201, an intangible type-dependent recovery cost construction portion 202, a dependent recovery cost propagation portion 203, and a dependent recovery cost integration portion 204.

The dependent recovery cost calculation procedure control portion 200 receives a state element model as an input, and calculates dependent recovery costs for all types.

The tangible type-dependent recovery cost construction portion 201 receives a tangible type (described later) as an input, and calculates a dependent recovery cost for the tangible type.

The intangible-type dependent recovery cost construction portion 202 receives an intangible type (described later) as an input, and calculates a dependent recovery cost for the intangible type.

The dependent recovery cost propagation portion 203 receives as input a type and all dependent recovery cost information (in the process of calculation), and supplements missing information in the dependent recovery cost information of the type according to inheritance information (described later) of the type.

The dependent recovery cost integration portion 204 receives a list of dependent recovery costs as an input, and integrates the list of dependent recovery costs into a single dependent recovery cost.

An abstract configuration and the data structure thereof in the present example embodiment will be described below. An abstract configuration refers to an abstract system configuration that includes undetermined parts regarding configuration and settings. An abstract configuration is that which carries out a role of defining a desired system without specifically mentioning the details of that system by writing down only the information that has been determined by the entity desiring an ICT system, i.e., information that indicates “what requirements the system should satisfy and what functions it should have.”

The basic configuration of an abstract configuration is a graph consisting of “nodes” that correspond to the functions and logical and physical components of a system, and “edges” that are stretched between two nodes to represent the relationship between those two nodes. The above-mentioned edges have a direction, and for an edge going from node n1 to node n2, node n1 is called the “source” and node n2 is called the “destination.” In the following, in a case where nodes and edges are referred to interchangeably, they will be collectively referred to as “entities.”

An entity has the following data: an “identifier” that uniquely identifies the entity throughout the entire system, a “type” that describes what concept the entity corresponds to, and a “satisfaction flag” that manages whether the expected configuration has been applied. The identity of an entity in two different abstract configurations is determined by an identifier. In other words, even if the types are different, if the identifier is the same, they are treated as the “same entity.”

In addition, a node has its own “initial state” as data. This “initial state” refers to any one of the states included in the “state element model (described later)” associated with its type.

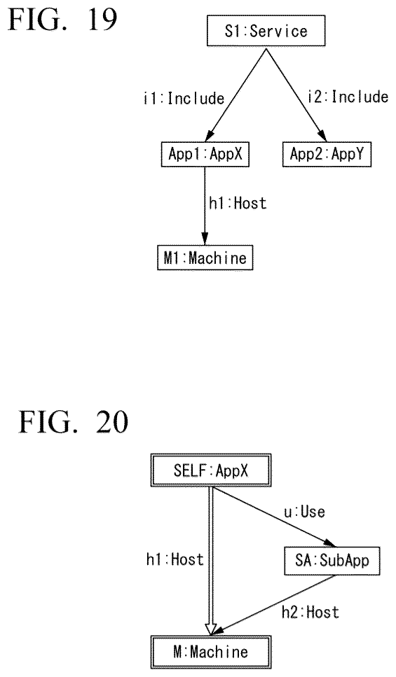

FIG. 19 is an example of an abstract configuration. As used herein, nodes are represented by rectangles labeled “(identifier): (type name)”, and edges are represented by arrows labeled “(identifier): (type name)”. From here on, “(identifier): (type name)” will be used to represent “an entity with the name (identifier) of type (type name)”.

The abstract configuration shown in FIG. 19 includes four nodes, S1:Service, App1:AppX, App1:AppY, and M1:Machine, and three edges, i1:Include, i2:Include, and h:Host. i1 is the edge from S1 to App1, i2 is the edge from S1 to App2, and h1 is the edge from App1 to M1. Intuitively, this indicates that S1 uses App1 and App2 as applications that constitute the service, and App1 is the machine that hosts M1.

Below, entity “types” and their corresponding “component models” are described in more detail.

The type of an entity has a role of indicating what kind of entity the entity is. There are two kinds of types: “abstract types” and “concrete types”. Abstract types refer to entities such as “Machine” or “HTTP connectable” that do not intuitively correspond to concrete components or connections that exist in the real world and that require further embodiment. On the other hand, concrete types indicate entities that correspond to concrete components or connection relationships that exist in reality, such as “(specific machine model number)” or “wired LAN connection.”

Also, inheritance relationships may be defined between different types. The inheritance relationships are explained below.

In a case where a type Ta inherits from a type Tb, it means that entities of type Ta can also be viewed as entities of type Tb. For example, the type MachineX, which corresponds to the model number of a specific machine, inherits the type PhMachine, which represents “all physical machines.” Furthermore, the type PhMachine inherits from the type Machine, which represents “any machine (whether physical or virtual)”. In addition, every abstract type has one or more concrete types that inherit it, and no types inherit a concrete type.

In addition, in this specification, it is assumed that a graph representing types and inheritance relationships is a collection of tree structures. That is, it is assumed that any type inherits from at most one type. Under this premise, a type that has no types that inherit from it is a concrete type.

(Supplement) It should be noted that the assumptions in the preceding paragraph are not related to the essence of each example embodiment of the present disclosure. In other words, the inheritance relationship structure does not necessarily have to be a set of tree structures.

We will write “Tb⇒Ta” to indicate that type Ta inherits type Tb. In a case where the relationship is T(m)⇒T(m−1)⇒, . . . , ⇒T(2)⇒T(1), we say that “T(1) is a descendant of T(m)” or “T(m) is an ancestor of T(1).” As shall be explained later, every entity having an abstract type will be embodied into an entity of a concrete type that is a descendant thereof during the automated design process, and must have all the expected constructs of its ancestor abstract entities.

This concludes the explanation of type inheritance relationships.

The model data that defines the information specific to each type is called the “constituent component model” of that type. Various information may be defined in the constituent component model, but in each example embodiment of the present disclosure, it is assumed that it includes “expected configuration” data and a “state element model.”

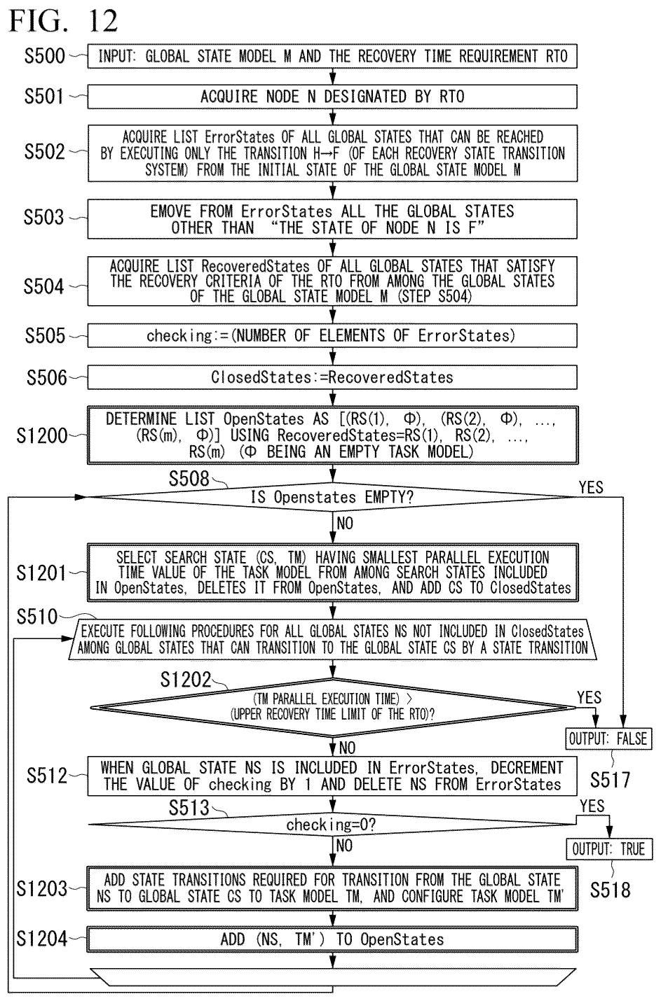

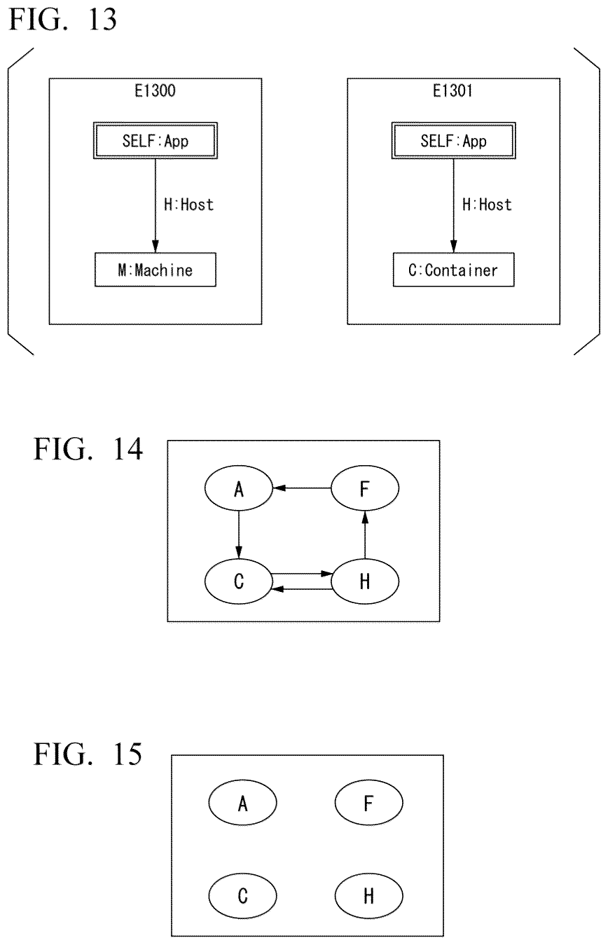

First, the “expected configuration” of a type refers to the surrounding configuration required for an entity having that type to operate normally in the system. For example, the fact that an “application” requires a “machine” to host it is expressed as an expected configuration of the App type, which corresponds to an “application.” E1300 in FIG. 13 is a graph expressing the above situation, in which an App type node SELF and a Machine type node M (representing a machine) are connected by a Host type edge H (representing a host relationship). “SELF” is a special identifier used here, and each expected configuration represents a structure required for an entity with the identifier “SELF” to operate correctly. That is, there is exactly one entity with identifier SELF in every expected configuration. Hereinafter, this “SELF” entity will be referred to as the target entity of the expected configuration.

In addition, there may be more than one expected configuration for a type. This means that any one of a number of expected configurations is expected to be applied. For example, FIG. 13 shows the expected configuration for two “App” type nodes, E1300 and E1301. A node “C: Container” representing an application container (Container type) is connected to E1301 instead of the “M: Machine” node in E1300. This means you can choose to host your application in an application container instead of on a machine.

Furthermore, some types do not have any expected configurations specified, which means that they do not require any dependent components and can function normally as system configuration components on their own.

The expected configuration specifies some entities, including the SELF node, as “prerequisite configurations.” A prerequisite configuration is a configuration that must be included in the abstract configuration to be applied, during application of a concrete configuration (described later). In the drawings in this specification, entities included in the prerequisite configuration are drawn with double lines.

For example, in E1300 and E1301 shown in FIG. 13, only the SELF node is drawn with a double line, which indicates that the prerequisite configuration for these expected configurations is only the SELF node.

On the other hand, as shown in FIG. 20, the prerequisite configuration may be a structure larger than the SELF node alone. The expected configuration shown in FIG. 20 includes the three nodes SELF:AppX, M:Machine, and SA:SubApp, and the three edges h1:Host, h2:Host, and u:Use, of which the three entities SELF, h1, and M are specified as the prerequisite configuration. This means that if the expected configuration described in FIG. 20 is applied, the abstract configuration to which it is applied must include “an AppX node, a Machine node, and a Host type edge extending from the former to the latter.”

The above is an explanation of the “expected configuration” of a type.

Secondly, a “state element model” of a type is a model that represents the state (in system recovery) of an entity having the type. The data structure of the state element model changes depending on whether the object type is “tangible” or “intangible.”

Among node types, there are those that undergo a state transition in a case where some operation is performed on them alone, and those that do not. For example, an App type node representing an application can be thought of as being able to transition to a “running” state, a “deleted” state, etc. by launching an executable file or uninstalling it. This type of node type is called a “tangible type.” On the other hand, a Service-type node, which corresponds to a “service” that runs a combination of multiple applications, can be thought of as transitioning its state in conjunction with the state transitions of the applications that make up the node. This type of node type is called an “intangible type.” All node types can be classified as either “tangible” or “intangible.”

All tangible types have a “recovery state transition system” as a state element model, and all intangible types have a “recovery state set” as a state element model.

A “recovery state transition system” is a graph structure in which the states of corresponding nodes are connected by state transitions. Here, the “state” of a node is a state related to recovery. In this specification, a structure as shown in FIG. 14 is assumed. In other words, we assume a graph structure with four types of states: “Fault has occurred (hereinafter referred to as state “F”),” “Deleted (hereinafter referred to as state “A”),” “Deployed (hereinafter referred to as state “C”),” and “In operation (hereinafter referred to as state “H”),” and four state transitions: state transition from F to A, state transition from A to C, state transition from C to H, and state transition from H to C. In a case where it is necessary to explicitly indicate the identifiers of the nodes, state s in the recovery state transition system of node N is written as “N:s”, and the transition from state s1 to s2 is written as “N: s1→s2”.

In addition, each transition of the recovery state transition system is associated with a type-specific “transition time cost,” that is, data on the time required to execute the transition. The transition time cost is specified for concrete types as a direct value, while for abstract types it is defined as the minimum of the values specified for all concrete types that are descendants of the abstract type. For example, if concrete types MachineX and MachineY are descendants of the Machine type, and the transition time costs of C→H are 10 and 7, respectively, then the transition time cost of C→H for the Machine type is 7.

A “recovery state set” is a recovery state transition system that does not include a state transition. In other words, it refers to a graph structure consisting of only nodes that contain states. In this specification, a structure as shown in FIG. 15 is assumed. In other words, we assume a graph structure that includes four types of states as nodes: “Fault has occurred (hereinafter referred to as state “F”),” “Deleted (hereinafter referred to as state “A”),” “Deployed (hereinafter referred to as state “C”),” and “In operation (hereinafter referred to as state “H”).”

(Supplement) However, the graph structures of the recovery state transition system and the recovery state set are not limited to those shown in FIGS. 14 and 15. It is not a problem to assume a completely different graph structure, and it is also possible to have a format in which different graph structures are associated with different types. However, the states always include a state corresponding to an abnormal state in a case where a fault occurs and a state corresponding to a normal operation state. In this embodiment, these are “F” and “H”, respectively.

The above is an explanation of the “state element model” of types.

Furthermore, in each example embodiment of the present disclosure, it is assumed that “recovery model” data is associated with and defined for each expected configuration of the node type. In the following description, the expected configuration with which a recovery model is associated is referred to as the “target configuration” of that recovery model.

The recovery models are explained below.

A recovery model is data that represents the dependency between the states of surrounding entities in a case where transitioning the state of a target entity in a situation where the target configuration exists in the vicinity of the target entity.

The recovery model is composed of state element models for all nodes included in the target configuration and dependencies defined between them.

The “dependencies” defined in the recovery model are data that are linked to the state transitions of the recovery state transition system and the states of the recovery state set, and are specifically defined as a data structure consisting of three types of data: “dependency items,” “dependency branches,” and “dependencies,” which are described below.

A dependency item is defined using a list S=[s(1), . . . , s(m)] of one or more states included in the recovery state transition system corresponding to node N, and is represented as “N: S”. If the state of node N is in any of s(1), . . . , s(m), then node N satisfies the dependency item N: [s(1), . . . , s(m)]. Also, in a case where the target structure contains a node N that satisfies the dependency item N: [s(1), . . . ,s(m)], it shall be said that the target structure itself satisfies the dependency item N: [s(1), . . . , s(m)].

A dependency branch is defined using one or more dependency items N(1):S(1), . . . , N(m):S(m) (where N(1), . . . , N(m) are all distinct nodes), and is represented as “{N(1):S(1), . . . , N(m):S(m)}”. In a case where a target configuration satisfies all dependency items N(1):S(1), . . . , N(m):S(m), the target configuration is said to satisfy the dependency branch {N(1):S(1), . . . , N(m):S(m)}.

A dependency is defined using zero or more dependency branches B(1), . . . , B(m), and is data denoted as “[B(1), . . . , B(m)]”. In a case where a target configuration satisfies any of the dependency branches B(1), . . . , B(m), the target configuration is said to satisfy the dependency [B(1), . . . , B(m)]. A dependency that consists of zero dependency branches is said to be empty, and an empty dependency is assumed to be unconditionally satisfied by any target configuration.

In this specification, in order to simplify the description, unless it causes confusion, the dependency [B] will be simply be denoted as B, and the dependency item N:{s} will simply be denoted as N: s.

The dependency associated with the transition N:s1→s2 in the recovery state transition system shall be denoted as DEP(N:s1→s2), and the dependency associated with the state N: s in the recovery state set as DEP(N:s).

In addition, for each state s(1), . . . , s(m) in the recovery state set, the following is assumed to hold. Whatever the state of the target configuration, exactly one of the dependencies DEP(s(1)), . . . , DEP(s(m)) is satisfied.

Next, the meaning of dependency shall be explained. The meaning of dependency is completely different depending on whether it is related to a recovery state transition system or a recovery state set.

First, for the transition N:s1→s2 of the recovery state transition system, unless the target configuration satisfies the dependency DEP(N:s1→s2), the recovery state transition system of node N cannot perform a state transition from s1 to s2. In other words, the dependency with respect to the recovery state transition system defines the “conditions related to the surrounding circumstances” for performing a state transition.

Second, for a state N: s in the recovery state set, the state of node N being in s is defined as a situation in which the target configuration satisfies the dependency DEP(s). In other words, dependency on an intangible state element directly corresponds to the “definition” of each state of the intangible state element, and expresses the property that an intangible node cannot transition states by itself, but rather its state changes in conjunction with the surrounding circumstances.

(Supplement) Regarding the dependencies attached to each intangible state, please note that by their very nature, two or more dependencies for the same recovery state set cannot be satisfied at the same time, and none of them can be satisfied at all. That is, no matter what state the surrounding structure is in, exactly one of the four dependencies assigned to each of states F, A, C, and H is satisfied.

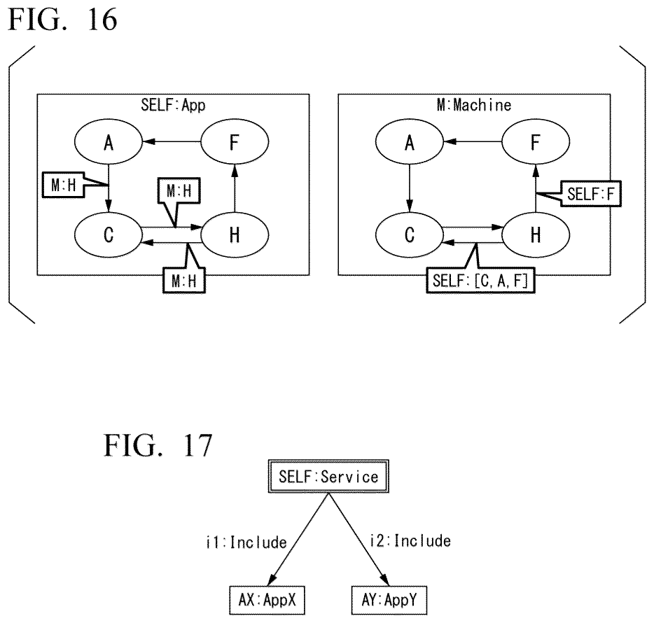

FIG. 16 is an explanatory diagram showing one recovery model for a tangible App, which corresponds to expected configuration E1300 in FIG. 13.

The recovery model shown in FIG. 16 includes the recovery state transition system corresponding to App-type node SELF and Machine-type node M, with the transitions A→C, C→H, and H→C of the recovery state transition system of SELF each assigned the dependency M:H, the transition H→F of the recovery state transition system of M assigned the dependency SELF:F, and the transition H→C the dependency SELF:{C,A,F}. For this reason, for example, the transition from state A to state C of an App type node to which expected configuration E1300 is applied cannot be executed unless the node of the host machine is in state H.

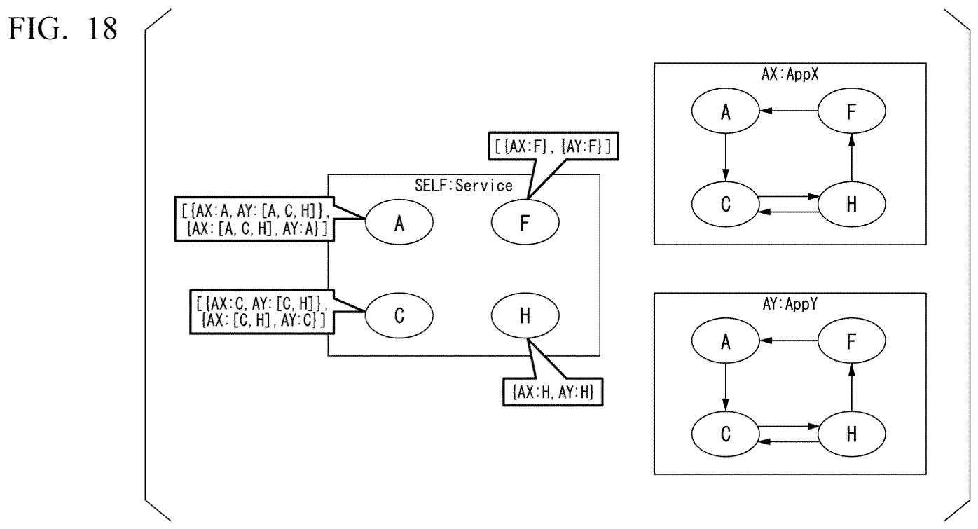

FIG. 18 is an explanatory diagram showing a recovery model for an intangible service, which corresponds to the expected configuration shown in FIG. 17.

The expected configuration shown in FIG. 17 indicates that the type Service representing a certain service needs to be composed of two applications AppX and AppY.

The recovery model shown in FIG. 18 includes a recovery state set corresponding to the Service type node SELF, and a recovery state transition system corresponding to the AppX type node AX and the AppY type node AY. In addition, state F in the recovery state set of SELF has a dependency [{AX:F}, {AY:F}], state A has a dependency [{AX:A,AY:[A,C,H]}, {AX:[A,C,H],AY:A}], state C has a dependency [{AX:C, AY:[C,H]}, {AX:[C,H],AY:C}], and state H has a dependency [{AX:H, AY:H}]. The state combination {AX:s(x), AY:s(y)} of the recovery state transition system of AX and AY satisfies one of the four dependencies above, and the state corresponding to the satisfied dependency becomes the state of the node SELF corresponding to {AX:s(x), AY:s(y)}.

The above is an explanation of the “types” and “component models” associated with entities.

The following describes an entity's “satisfaction flag.”

An entity of type T is associated with a set of flags that use all of the ancestor types of type T(1), T(2), . . . , T(m) and the type T itself as keys. This is called the satisfaction flag of the entity in question. Each flag is assigned a value of TRUE or FALSE.

In a case where all the satisfaction flags are TRUE, the satisfaction flags are said to be sufficient, and in a case where any are FALSE, the satisfaction flags are said to be deficient. In particular, an entity is said to be deficient with respect to type T(i) in a case where the flag with respect to the type T(i) is FALSE. As will be explained later, one can apply the expected configuration of type T(i) to any missing entities with respect to type T(i), and the flag will become TRUE upon application.

In addition, entities that are originally included in the abstract configuration and entities newly generated by application of the expected configuration (described later) are assigned a satisfaction flag with the entity and its ancestor types as keys, and the initial value of each flag is FALSE if the expected configuration exists for the type that is the key, and TRUE otherwise.

This concludes the explanation of the entity's “satisfaction flag.”

Next, the “global state model” of an abstract configuration shall be explained.

The “global state model” of an abstract configuration is a data structure consisting of state element models for all nodes contained in the abstract configuration and the dependencies between them. As with the recovery model, transitions in each recovery state transition system can only be executed if they satisfy dependencies.

Each time an expected configuration is applied in the automated design procedure, the dependencies defined in the recovery model of that expected configuration are added to the global state model of the abstract configuration. It may be considered that dependencies are not defined in the global state model corresponding to the functional requirements received as input by the system configuration derivation device 100, and dependencies are added only in a case where the expected configuration is applied.

(Supplement) However, each example embodiment of the present disclosure does not require that there be no dependency in the global state model corresponding to the functional requirement. An initial value of the dependency may be set in the global state model of the functional requirements based on some criteria.

The global state model itself can be regarded as one large state transition system (representing the state transitions of the system). The state of the global state model in a case where it is considered as a single state transition system is called the “global state,” and is defined as the state data {n(1):s(1), . . . , n(m):s(m)} that combines the states s(1), . . . ,s(m) of each node n(1), . . . ,n(m) in the abstract configuration. The initial state of the global state model is a compilation of the initial states of each node. The state of the global state model changes by causing a transition of one of the recovery state transition systems contained in the global state model. In other words, in a case where the state of node n(i) transitions from A to C, the global state of the abstract construction transitions from {n(1):s(1), . . . , s(i): A, . . . , n(m):s(m)} to {n(1):s(1), . . . , s(i): C, . . . , n(m):s(m)}.

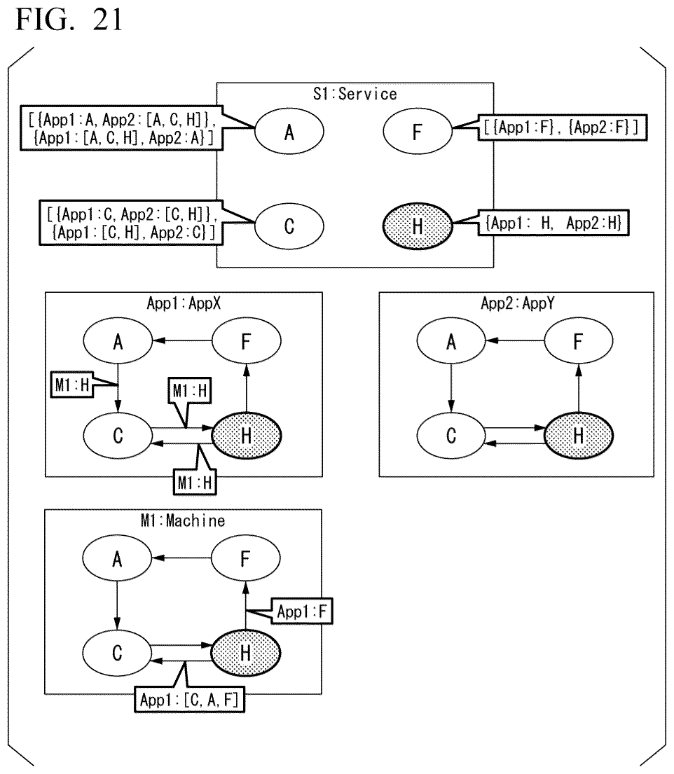

FIG. 21 is an example of a global state model corresponding to the abstract configuration shown in FIG. 19. Here, it is assumed that the initial state of all nodes is H. The initial state of each node is represented by a filled circle, and the initial state of this global state model is represented as {S1:H, App1:H, App2:H, M1:H}.

The initial state {S1:H, App1:H, App2:H, M1:H} of the global state model shown in FIG. 21 can be transitioned to global states {S1:F, App1:F, App2:H, M1:H} and {S1:F, App1:H, App2:F, M1:H} by executing the transition H→F for App1 and App2, respectively. Here, the state of S1 also transitions in conjunction with the transition of App1 (and App2). On the other hand, the transition H→F of M1 cannot be executed because the attached dependency is not satisfied in the initial state, but it can be executed in the global state {S1:F, App1:F, App2:H, M1:H} where App1 has transitioned to F, and in a case where executed, the transition to the global state {S1:F, App1:F, App2:H, M1:F} occurs.

The above is a description of the “global state model” of abstract configuration.

Next, the recovery time requirement will be described. There are two types of recovery time requirements: a “temporary recovery time requirement” and a “full recovery time requirement”, each of which is defined for a node.

The “temporary recovery time requirement” for node N specifies the upper limit of the time from in a case where a failure occurs in node N until the state of node N returns to a normal operating state.

The “full recovery time requirement” for node N specifies the upper limit of the time required from in a case where a failure occurs in node N until the state of all nodes that depend on the normal operation of node N are restored to their initial states.

Each type of recovery time requirement imposes an upper limit on the time required for recovery. This is called the “upper recovery time limit” of the recovery time requirement.

This concludes the explanation of the recovery time requirement.

Next, embodiment of the abstract configuration will be described. Two types of embodiment operations can be performed on abstract configurations: “application of expected configuration” and “type refinement.” Either operation results in one or more new abstract configurations.

First, the “application of the expected configuration” to the abstract structure D is performed according to the following steps.
1. Select an entity e in D that is missing a satisfaction flag.
2. Select the type T that is missing for entity e.
3. For each expected configuration EX of type T such that D contains a prerequisite configuration, output the result of applying the following operation to the abstract configuration D as the result of the “application of expected configuration” operation.

The following operation is as follows: “Add the necessary entities so that the expected structure EX appears in such a way that matches the entity e with SELF. Then, update the satisfaction flag for the entity e's type T to TRUE. However, if there are multiple ways to make it appear, output them all as separate abstract structures.”

A supplement to Step 3, “In a case where there are multiple ways to make it appear.” In a case where applying the expected configuration shown in E1300 in FIG. 13 to an abstract configuration D that has only two nodes, an App type node A1 and a Machine type node M1, and no edges, there are two methods for applying the expected configuration to the abstract configuration D: “(1) Add a new Machine type node M2 to D, and further add a HOST type edge H2 connecting A1 and M2” and “(2) Add a HOST type edge H1 connecting A1 and M1.” In this way, multiple candidates may be considered for how the expected configuration is added to the abstract configuration, and Step 3 outputs all of these as the results of the “application of expected configuration” operation.

Second, the “type refinement” operation for an abstract configuration D is performed according to the following steps:
1. Select an entity e in D that has an abstract type.
2. For all types T′ that inherit the type T of entity e, apply the following operation to the abstract configuration D and output the result as the result of the “type refinement” operation.

“Change the type of entity e to T′ and add a flag with T′ as the key to the satisfaction flag. However, the value of the flag for T′ is FALSE if T′ has one or more expected configurations, and TRUE if T′ has none.”

The above is a description of the embodiment of an abstract configuration.

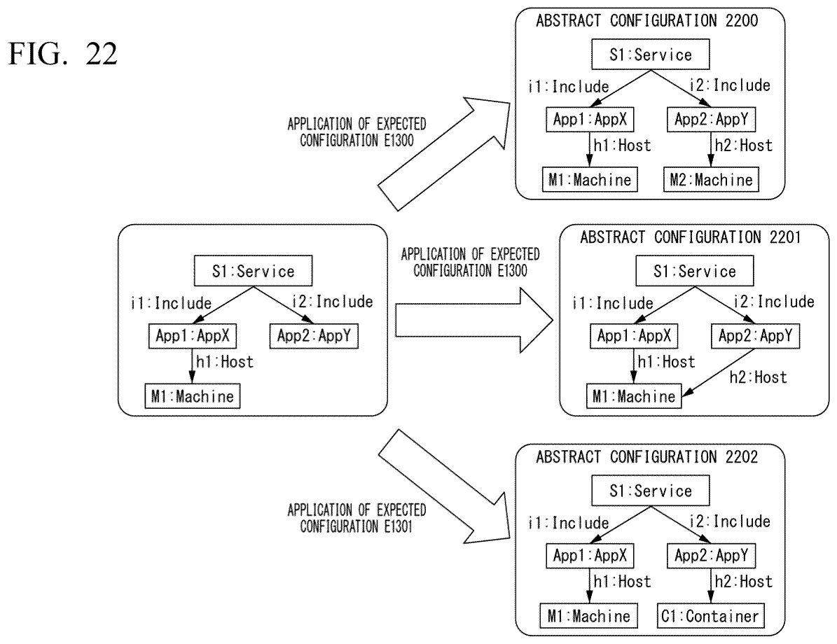

Next, concrete examples will be used to explain the embodiment of the abstract structure. FIG. 22 is a diagram for explaining an example in which FIG. 19 is embodied in three different ways using the expected configuration shown in FIG. 13.

The abstract configuration 2200 is a case in which the expected configuration E1300 of type App of node App2 is applied to generate and connect a new Machine type node M2.

The abstract configuration 2201 is also a case in which the expected configuration E1300 of the type App of the node App2 is applied, but instead of generating a new node, the Machine type node M1 already included in FIG. 19 is connected.

The abstract configuration 2202 is also a case in which the expected configuration E1301 of the type App of the node App2 is applied, and a new Container type node C1 is generated and connected.

The above three cases are all transformations that advance one step toward embodiment by applying the expected configuration to the node App2, which is an abstract element, with respect to the original abstract configuration in FIG. 19.

Furthermore, it is worth noting that although the abstract configuration 2200 and the abstract configuration 2201 apply the exact same expected configuration to the exact same nodes, differences in the embodiment methods result in differences in the resulting configurations. In other words, even if the original abstract configuration and the expected configuration to be applied are exactly the same, the transformation will proceed into various configurations depending on the differences in the transformation methods, resulting in various concrete configurations.

The above is a description of rewriting an abstract configuration through embodiment.

Next, precise definitions of concrete configurations derived from each example embodiment of the present disclosure will be described.

In the present example embodiment, a concrete configuration refers to an abstract configuration that has been completely embodied. Here, an abstract configuration being “completely embodied” means that it satisfies all of the following three types of embodiment conditions: (embodiment condition 1), (embodiment condition 2), and (embodiment condition 3).
(Embodiment condition 1) The abstract configuration does not include any node having an abstract type.
(Embodiment condition 2) The abstract structure does not include any edge having an abstract type.
(Embodiment condition 3) The abstract configuration does not include any entity whose satisfaction flag is missing.

From the definition of the embodiment conditions, it can be said that an abstract configuration that does not include unit requirements is an ICT system in which there are no ambiguous parts and all the parts necessary for operation (=the expected configuration for each entity) are present. Therefore, the concrete configuration corresponds to a system that is functionally fully operational.

### (Operation)

The system configuration derivation device 100 of the present example embodiment receives, as input, an abstract configuration representing functional requirements and a recovery time requirement for a node included in the abstract requirement, and outputs a concrete configuration that satisfies both the functional requirements and the recovery time requirement.

The processing of each unit of the system configuration derivation device 100 will be described in detail below.

The dependent recovery cost calculation portion 102 of the present example embodiment receives as input the entire component model corresponding to each type, and calculates the dependent recovery cost for each transition of the recovery state transition system included in each component model.

First, the meaning of the “dependent recovery cost” output by the dependent recovery cost calculation portion 102 will be explained. In order to recover a system from a failure, it is necessary to transition an entity in a failure state to another state. In order to do this, the dependencies of the recovery model must be satisfied, so the underlying structure must be transitioned in order to recover the element in question. In this case, if a failure occurs in the underlying structure in addition to the entity in question, it is necessary to restore these elements in addition to the entity in question in order to restore it. Assuming that each entity included in the target configuration is in a failure state, the state transition of other entities required to cause the entity to transition from the “failure” state (F) to another state is called the “dependent recovery cost.”

Furthermore, with respect to the surrounding configuration of an entity, an expected configuration regarding the entities contained therein is additionally embodied. Therefore, the recovery cost that takes these factors into consideration is called the dependent recovery cost.

Dependency recovery cost is essentially a list of data that means “a node of type T needs to be moved from state F to another state s.” This data, which means that “it is necessary to move a node of type T from state F to another state s,” is called the “unit recovery cost” and is written as Cost(T:s).

In addition, as described later, in the present example embodiment, in order to obtain data that is somewhat approximate rather than the actual dependent recovery cost, a unit recovery cost that expresses the “cost required to recover nodes of types T(1), . . . , T(m)” is used for multiple types T(1), . . . , T(m) rather than a single type. Such a unit recovery cost is used to ignore the specific recovery procedure and to take into account only the time cost L required for recovery. Therefore, the above unit recovery cost will be written as AbsCost(T(1), . . . , T(m):L).

In a case where it is necessary to distinguish between the two types of unit recovery costs mentioned above, we call Cost(T:s) the “concrete” unit recovery cost and AbsCost(T(1), . . . , T(m):L) the “abstract” unit recovery cost.

In addition, the “required time” for each unit recovery cost is defined as follows: 1 to 3.
1. In a case where T is a tangible type, the time required for a concrete unit recovery cost Cost(T:s) is the sum of the transition time costs of the state transitions required to move T from state F to state s on the state element model.
2. In a case where T is intangible, the time required for a concrete unit recovery cost Cost(T:s) is assumed to be 0.
3. Let the time required for the abstract unit recovery cost AbsCost(T(1), . . . , T(m):L) be L.

This concludes the explanation of dependent recovery costs.

However, since it is generally difficult to enumerate all structures that can be derived from the expected configuration of a certain entity, the dependent recovery cost calculation portion 102 of the present example embodiment obtains and outputs a subset of the actual dependent recovery costs.

In the following, an overview of the dependent recovery cost actually calculated by the dependent recovery cost calculation portion 102 of the present example embodiment will be described using a specific example.

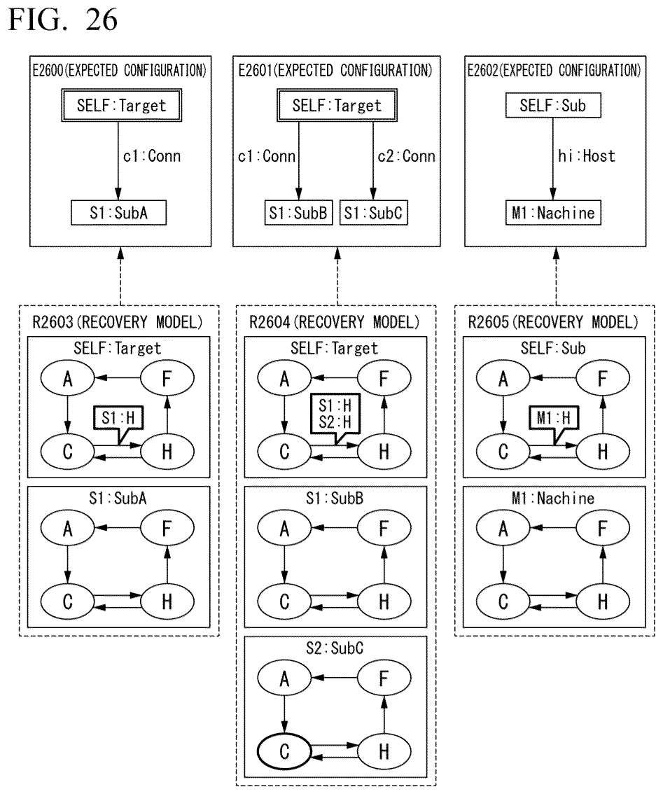

To illustrate the dependent recovery cost, the expected configuration and recovery model shown in FIG. 26 are used as the premise. Here, we assume an environment with six node types: Target, Sub, SubA, SubB, SubC, and Machine, and two edge types: Conn and Host. (This is a formal illustration for explanatory purposes and does not represent any specific system components.)

All node types are tangible types. In addition, Target, SubA, SubB, SubC, Machine, Conn, and Host are concrete types, and types other than Target do not have expected configurations. Sub is an abstract type and is inherited by SubA, SubB, and SubC.

As shown in FIG. 26, the Target type has two expected configurations E2600 and E2601, and the Sub type has one expected configuration E2602. Furthermore, recovery models R2603, R2604, and R2605 are linked to the expected configurations E2600, E2601, and E2602, respectively.

The transition time costs of each transition in the recovery state transition systems of SubA, SubB, and SubC are defined as follows: (SubA) The cost of A→C is 2, the cost of C→H is 3, and the costs of other transitions are 0; (SubB) The cost of A→C is 2, the cost of C→H is 1, and the costs of other transitions are 0; (SubC) The cost of A→C is 4, the cost of C→H is 2, and the costs of other transitions are 0.

Under the above assumptions, in a case where considering how to embody functional requirements that only include Target-type nodes, the following three patterns are possible. (Note that here, the state transition in the steps of F→A→C→His called “recovery.”)
(Pattern 1) “SubA type node n1 and Machine type node n2 are generated, and recovery of the Target requires the additional recovery of two nodes, n1 and n2.”
(Pattern 2) “SubB type node n1, SubC type node n2, and Machine type node n3 are generated, and recovery of the Target requires the additional recovery of three nodes, n1, n2, and n3.”
(Pattern 3) “SubB type node n1, SubC type node n2, Machine type nodes n3 and n4 are generated, and recovery of the Target requires additional recovery of the four nodes n1, n2, n3, and n4.”

The dependent recovery cost calculation portion 102 of the present example embodiment obtains a lower limit of the cost additionally required for restoration as the dependent recovery cost. Therefore, in the above situation, the recovery cost required to restore a Target type node from state F to state H is considered to be its own recovery cost plus the recovery cost required to recover one Machine type node and the recovery cost required to recover one SubA, SubB, or SubC type node.

In fact, in a case where the state element model shown in FIG. 26 is input to the dependent recovery cost calculation portion 102 of the present example embodiment, the value [Cost(Machine:H), AbsCost(SubA, SubB, SubC:3)] is returned as the recovery cost DC[Target][H] of Target type F→H. As will be explained in detail later, Cost(Machine:H) means “the recovery cost of transitioning the Machine type state from F to H”, and AbsCost(SubA,SubB,SubC:3) means “the recovery cost corresponding to any of the components SubA, SubB, or SubC, with a transition time cost of 3.”

The above is an explanation of a specific example of the value of the dependent recovery cost output by the dependent recovery cost calculation portion 102 of the present example embodiment.

The process of each part of the dependent recovery cost calculation portion 102 will be described in detail below.

### (Operation of the Dependent Recovery Cost Calculation Procedure Control Portion 200)

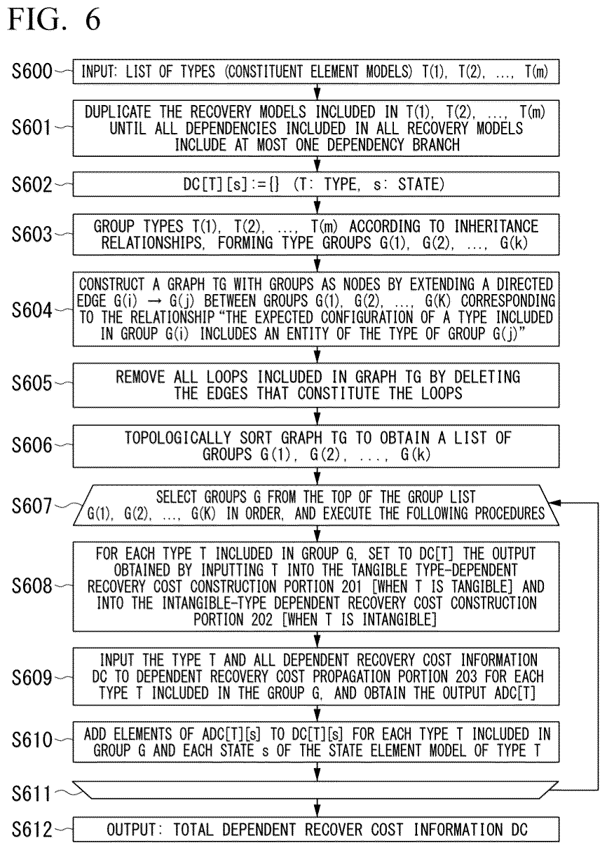

First, the operation of the dependent recovery cost calculation procedure control portion 200 of the present example embodiment will be described in detail. FIG. 6 is a flowchart showing the overall operation of the dependent recovery cost calculation procedure control portion 200 of the present example embodiment.

The dependent recovery cost calculation procedure control portion 200 receives as input a list of types (constituent component models) T(1), T(2), . . . , T(m) (Step S600).

The dependent recovery cost calculation procedure control portion 200 performs the following “duplication” operation on the recovery models included in T(1), T(2), . . . , T(m) until all dependencies included in all recovery models include at most one dependency branch. The “duplication” operation described below is an operation in which, for a recovery model that includes a dependency [B(1), B(2), . . . , B(m)] with two or more dependency branches, “duplicate” the recovery model for each target configuration by the number m of dependency branches included, and correspond to dependencies [B(1)], [B(2)], . . . , [B(m)] with only one dependency branch, respectively (Step S601).

(Attention) This “duplicated” state element model data is used only while the dependent recovery cost calculation portion 102 is in operation, and the original state element model data is referenced in the configuration embodiment portion 101.

The dependent recovery cost calculation procedure control portion 200 initializes the total dependent recovery cost information DC as follows. Since the total dependent recovery cost information has a dictionary structure with two keys, namely, type and transition destination state, it is initialized with DC[T][s]:={ } (empty dictionary) for each type T and each state s(other than F) (Step S602).

The dependent recovery cost calculation procedure control portion 200 groups types T(1), T(2), . . . , T(m) according to inheritance relationships, forming type groups G(1), G(2), . . . , G(k). In the present specification, it is assumed that the inheritance relationship of types is a set of tree structures, so that one tree structure corresponds to one group (Step S603).

The dependent recovery cost calculation procedure control portion 200 constructs a graph TG with groups as nodes by extending a directed edge G(i)→G(j) between groups G(1), G(2), . . . , G(k) corresponding to the relationship “the expected configuration of a type included in group G(i) includes an entity of the type of group G(j)” (Step S604).

The dependent recovery cost calculation procedure control portion 200 removes all loops included in the graph TG by deleting the edges that constitute the loops (Step S605).

The dependent recovery cost calculation procedure control portion 200 topologically sorts the graph TG to obtain a list of groups G(1), G(2), . . . , G(k) (Step S606). (That is, if TG has an edge G(i)→G(j), then G(j) will appear earlier in the list.)

The dependent recovery cost calculation procedure control portion 200 selects groups G from the top of the group list G(1), G(2), . . . , G(k) in order, and executes Step S608 for each group (Step S607).

For each type T included in group G, the dependent recovery cost calculation procedure control portion 200 inputs type T into the tangible type-dependent recovery cost construction portion 201 for tangible types and into the intangible-type dependent recovery cost construction portion 202 for intangible types, and sets the obtained output as DC[T] (Step S608).

The dependent recovery cost calculation procedure control portion 200 inputs the type T and all dependent recovery cost information DC to the dependent recovery cost propagation portion 203 for each type T included in the group G, and obtains the output ADC[T] (Step S609).

The dependent recovery cost calculation procedure control portion 200 adds elements of ADC[T][s] to DC[T][s] for each type T included in group G and each state s of the state element model of type T (Step S610).

After executing the procedures from Step S608 to Step S610 for all groups G(1), G(2), . . . , G(k), the dependent recovery cost calculation procedure control portion 200 proceeds to Step S612 (Step S611).

The dependent recovery cost calculation procedure control portion 200 outputs the total dependent recovery cost information DC (Step S612).

The above is a description of the operation of the dependent recovery cost calculation procedure control portion 200 of the present example embodiment.

### (Operation of the Tangible Type-Dependent Recovery Cost Construction Portion 201)

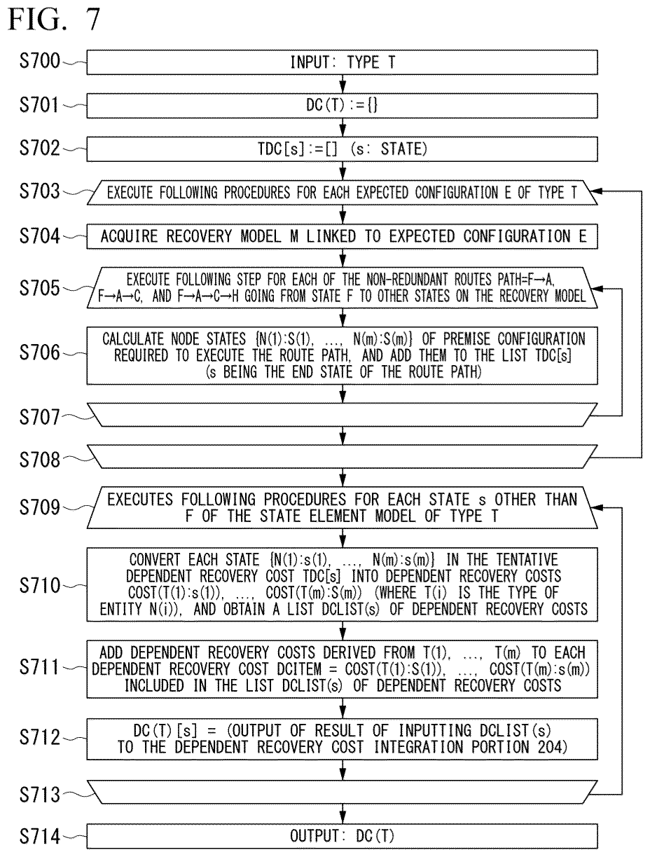

Next, the operation of the tangible type-dependent recovery cost construction portion 201 of the present example embodiment will be described. FIG. 7 is a flowchart showing the overall operation of the tangible type-dependent recovery cost construction portion 201 of the present example embodiment.

The tangible type-dependent recovery cost construction portion 201 receives a type T as an input (Step S700).

The tangible type-dependent recovery cost construction portion 201 initializes the dependent recovery cost DC(T) of T with DC(T):={ } (empty dictionary) (Step S700).

The tangible type-dependent recovery cost construction portion 201 initializes the provisional dependent recovery cost TDC as follows. That is, since the provisional dependent recovery cost has a dictionary structure whose key is the state of the state element model of T, it is initialized with TDC[s]: =[ ] (empty list) for each state s (other than F) (Step S702).

The tangible type-dependent recovery cost construction portion 201 executes the procedures from Step S704 to Step S707 for each expected configuration E of type T (Step S703).

The tangible type-dependent recovery cost construction portion 201 acquires the recovery model M linked to the expected configuration E (Step S704).

The tangible type-dependent recovery cost construction portion 201 executes Step S706 for each of the non-redundant routes PATH=F→A, F→A→C, and F→A→C→H going from state F to other states in the recovery model (Step S705).

The tangible type-dependent recovery cost construction portion 201 calculates the node states {n(1):s(1), . . . , n(m):s(m)} of the target configuration required to execute the route PATH, and adds them to the list TDC[s] (Step S706) (s being the end state of the route PATH).

(Step S706 Supplement 1) Here, a supplement will be given regarding the calculation of “the node state of the target configuration required to execute the route PATH”. It is assumed that the states of all state element models included in the recovery model M are in F, and in order to transition the state element model corresponding to the node SELF along the route PATH by a state transition from there, it is considered that the state element models of the surrounding nodes are transitioned to the minimum extent necessary (to satisfy the dependency).

(Step S706 Supplement 2) The states of the surrounding nodes {n(1):s(1), . . . , n(m):s(m)} at the stage in a case where the transition along the PATH is completed is the “node states of the target configuration required to execute the route PATH.” In order to restore an entity of type T with expected configuration EX, the surrounding configurations must be at least {n(1):s(1), . . . , n(m):s(m)}, which incurs additional transition costs.

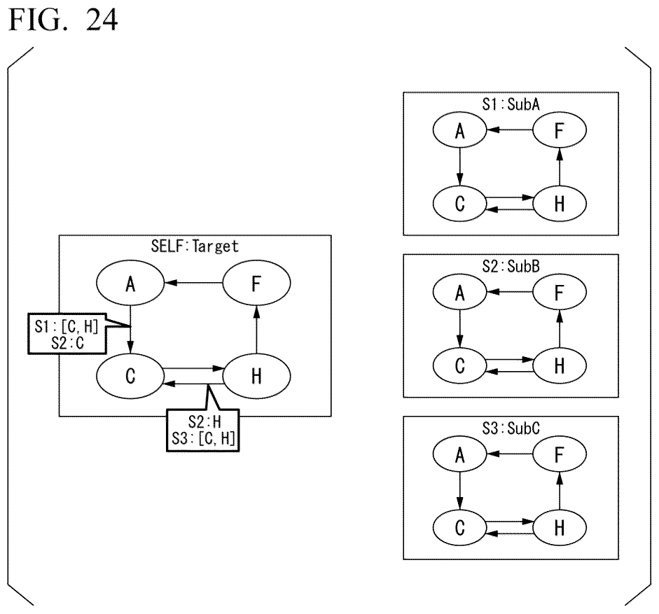

(Supplementary Note 3 for Step S706) For a concrete explanation, consider executing Step S706 for the recovery model shown in FIG. 24. FIG. 24 shows a recovery model for a Target-type node, which includes three peripheral components S1:SubA, S2:SubB, and S3:SubC. Furthermore, as dependencies, {S1:[C,H], S2:C} is assigned to the transition SELF:A→C, and {S2:H, S3:[C,H]} is assigned to the transition SELF:C→H.

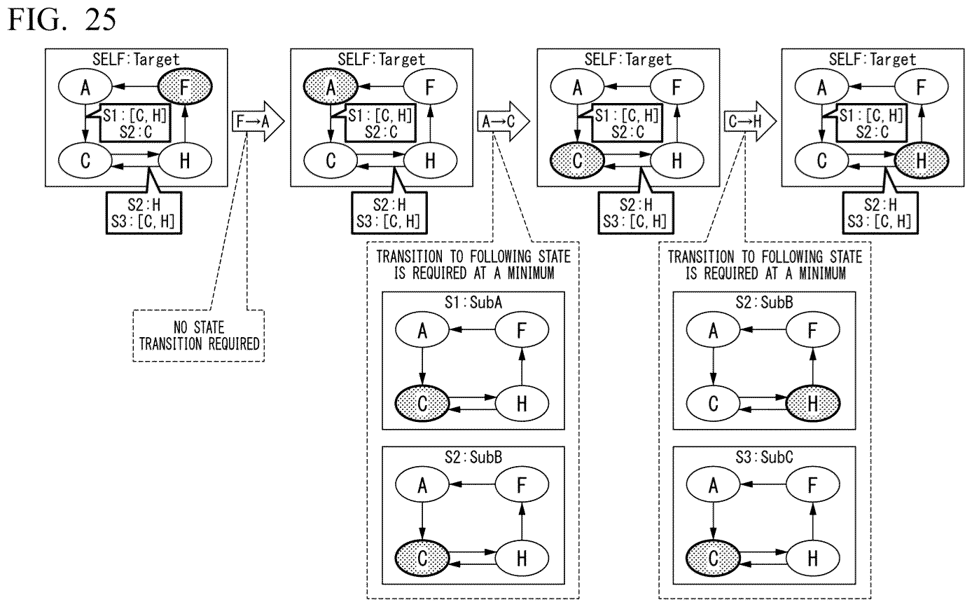

(Step S706 Supplement 4) FIG. 25 is a diagram showing the node states of the target configuration required for executing each transition SELF:F→A, SELF:A→C, and SELF:C→H. No states are required to execute the transition SELF:F→A, node states {S1:C, S2:C} are required to execute the transition SELF:A→C, and node states {S2:H, S3:C} are required to execute the transition SELF:C→H. Based on this information, we can see that no node states in the target configuration are required to execute the route F→A, but node states {S1:C, S2:C} are required to execute the route F→A→C. Furthermore, in order to execute the route F→A→C→H, it is necessary to transition to a state for executing A→C, and then to a state for executing C→H. Therefore, it can be seen that the node information {S1:C, S2:H, S3:C} is required.

(Supplementary Note 5 for Step S706) Therefore, in a case where Step S706 is executed for the recovery model shown in FIG. 24, TDC[A]={ }, TDC[C]={S1:C, S2:C}, and TDC[H]={S1:C, S2:H, S3:C} are set. The above is supplementary information for Step S706.

After executing Step S706 for all the paths, the tangible type-dependent recovery cost construction portion 201 proceeds to Step S708 (Step S707).

After executing the procedures from Step S704 to Step S707 for all expected configurations, the tangible type-dependent recovery cost construction portion 201 proceeds to Step S709 (Step S708).

The tangible type-dependent recovery cost construction portion 201 executes the procedures from Step S710 to Step S712 for each state s other than F of the state element model of type T (Step S709).

The tangible type-dependent recovery cost construction portion 201 converts each state {n(1):s(1), . . . , n(m):s(m)} in the tentative dependent recovery cost TDC[s] into dependent recovery costs Cost(T(1):s(1)), . . . , Cost(T(m):s(m)) (where T(i) is the type of entity n(i)), and obtains a list DCList(s) of dependent recovery costs (Step S710).

The tangible dependent recovery cost construction portion 201 adds dependent recovery costs derived from T(1), . . . , T(m) to each dependent recovery cost DCItem=Cost(T(1):s(1)), . . . , Cost(T(m):s(m)) included in the list DCList(s) of dependent recovery costs. That is, the contents of DC[T(i)] [s(i)] for each Cost(T(i):s(i)) are all added to DCItem (Step S711).

The tangible type-dependent recovery cost construction portion 201 inputs DCList(s) to the dependent recovery cost integration portion 204, and sets the output from the dependent recovery cost integration portion 204 to DC(T)[s] (Step S712).

The tangible type-dependent recovery cost construction portion 201 executes the procedures from Step S710 to Step S712 for all states s other than F of the state element model of type T, and then proceeds to Step S714 (Step S713).

The tangible type-dependent recovery cost construction portion 201 outputs DC(T) to the dependent recovery cost calculation procedure control portion 200 (Step S714).

### (Operation of the Intangible Type-Dependent Recovery Cost Construction Portion 202)

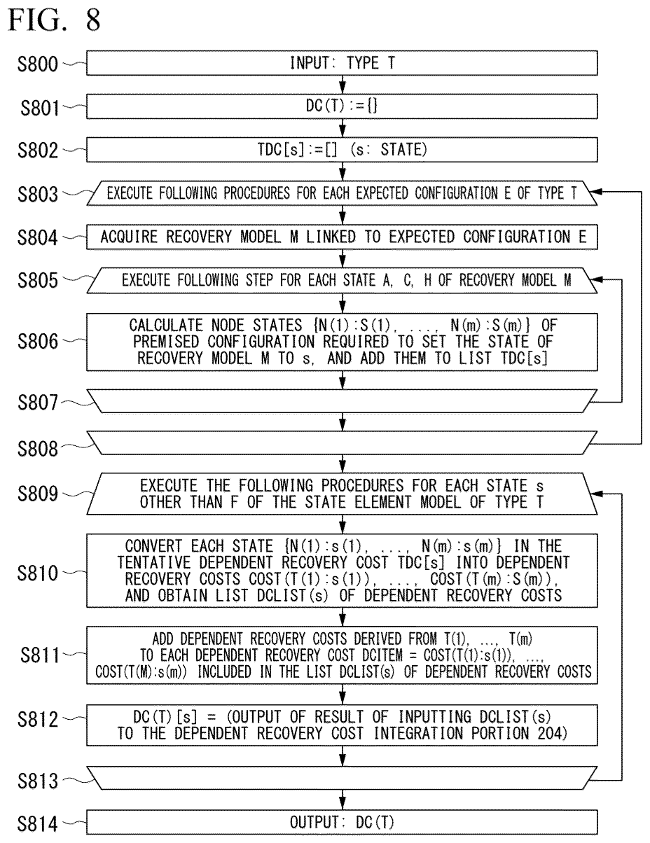

Next, the operation of the intangible-type dependent recovery cost construction portion 202 of the present example embodiment will be described. FIG. 8 is a flowchart showing the overall operation of the intangible type-dependent recovery cost construction portion 202 of the present example embodiment.

The intangible type-dependent recovery cost construction portion 202 receives a type T as an input (Step S800).

The intangible type-dependent recovery cost construction portion 202 initializes the dependent recovery cost DC(T) of T with DC(T):={ } (empty dictionary) (Step S801).

The intangible type-dependent recovery cost construction portion 202 initializes the provisional dependent recovery cost TDC as follows. That is, since the provisional dependent recovery cost has a dictionary structure whose key is the state of the state element model of T, it is initialized with TDC[s]:=[ ] (empty list) for each state s (other than F) (Step S802).

The intangible type-dependent recovery cost construction portion 202 executes the procedures from Step S804 to Step S807 for each expected configuration E of type T (Step S803).

The intangible type-dependent recovery cost construction portion 202 acquires the recovery model M linked to the expected configuration E (Step S804).

The intangible type-dependent recovery cost construction portion 202 executes Step S806 for each state s=A, C, H of the recovery model M (Step S805).

The intangible type-dependent recovery cost construction portion 202 calculates the node states {n(1):s(1), . . . , n(m):s(m)} of the target configuration required to set the state of the recovery model M to s, and adds them to the list TDC[s] (Step S806).

(Step S806 Supplement 1) Here, a supplement will be given regarding the calculation of “the node state of the target configuration required to set the state of recovery model M to s.” By definition, to put a recovery model M into a state s, we simply need to satisfy the dependencies associated with s. Therefore, first assume that the states of all state element models included in the recovery model M are in F, and consider making the state element models of the surrounding nodes transition as little as possible (to satisfy the dependency) so as to satisfy the dependency linked to s.

(Step S806 Supplement 2) The states of the surrounding nodes at the stage where the dependencies are satisfied {n(1):s(1), . . . , n(m):s(m)} are the “node states of the target configuration required to set the state of recovery model M to s.” To recover an entity of type T with expected configuration EX, it is necessary to put at least the surrounding configurations into the states {n(1):s(1), . . . , n(m):s(m)}, which incurs additional transition costs. The above is supplementary information for Step S806.

After executing Step S806 for all states, the intangible type-dependent recovery cost construction portion 202 proceeds to Step S808 (Step S807).

After executing the procedures from Step S804 to Step S807 for all expected configurations, the intangible type-dependent recovery cost construction portion 202 proceeds to Step S809 (Step S808).

The intangible type-dependent recovery cost construction portion 202 executes the procedures from Step S810 to Step S812 for each state s other than F of the state element model of type T (Step S809).

The intangible type-dependent recovery cost construction portion 202 converts each state {n(1):s(1), . . . , n(m):s(m)} in the tentative dependent recovery cost TDC[s] into dependent recovery costs Cost(T(1):s(1)), . . . , Cost(T(m):s(m)) (where T(i) is the type of entity n(i)), and obtains a list of dependent recovery costs DCList(s) (Step S810).

The intangible dependent recovery cost construction portion 202 adds dependent recovery costs derived from T(1), . . . , T(m) to each dependent recovery cost DCItem=Cost(T(1):s(1)), . . . , Cost(T(m):s(m)) included in the list DCList(s) of dependent recovery costs. That is, the contents of DC[T(i)] [s(i)] for each Cost(T(i):s(i)) are all added to DCItem (Step S811).

The intangible type-dependent recovery cost construction portion 202 inputs DCList(s) to the dependent recovery cost integration portion 204, and sets the output from the dependent recovery cost integration portion 204 to DC(T)[s] (Step S812).

The intangible type-dependent recovery cost construction portion 202 executes the procedures from Step S810 to Step S812 for all states s other than F of the state element model of type T, and then proceeds to Step S814 (Step S813).

The intangible type-dependent recovery cost construction portion 202 outputs DC(T) to the dependent recovery cost calculation procedure control portion 200 (Step S814).

The above is a description of the operation of the intangible type-dependent recovery cost construction portion 202 of the present example embodiment.

### (Operation of the Dependent Recovery Cost Integration Portion 204)

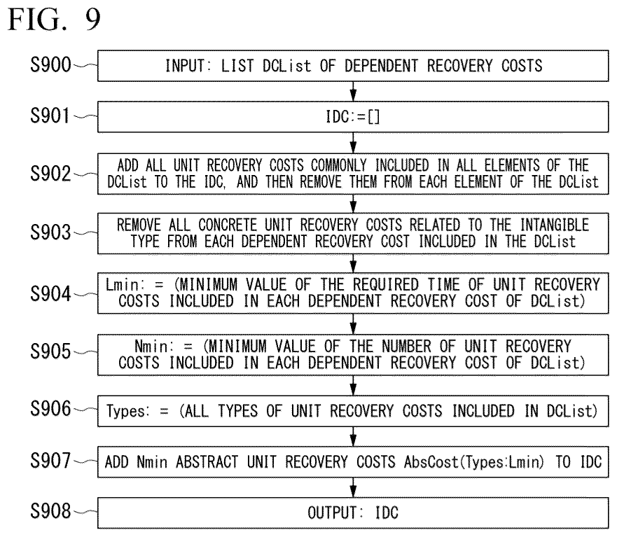

Next, the operation of the dependent recovery cost integration portion 204 of the present example embodiment will be described. FIG. 9 is a flowchart showing the overall operation of the dependent recovery cost integration portion 204 of the present example embodiment.

The dependent recovery cost integration portion 204 receives the list DCList of dependent recovery costs as an input (Step S900).

The dependent recovery cost integration portion 204 initializes the integrated dependent recovery cost IDC to be output with an empty list (Step S901).

The dependent recovery cost integration portion 204 adds all unit recovery costs commonly included in all elements of the DCList to the IDC, and then removes them from each element of the DCList (Step S902).

The dependent recovery cost integration portion 204 removes all concrete unit recovery costs related to the intangible type from each dependent recovery cost included in the DCList (Step S903).

The dependent recovery cost integration portion 204 obtains the minimum value of the required time of all the unit recovery costs included in the DCList, and sets this to Lmin (Step S904).

The dependent recovery cost integration portion 204 obtains the minimum value of the number of unit recovery costs included in each dependent recovery cost in the DCList, and sets this value as Nmin (Step S905).

The dependent recovery cost integration portion 204 constitutes a list Types that lists all the types of unit recovery costs included in DCList (excluding duplicates). That is, T(1) for the concrete unit recovery cost Cost(T(1):s(1)) and all of T(1), T(2), . . . , T(m) for the abstract unit recovery cost AbsCost(T(1), T(2), . . . , T(m):L) are collected into one list (Step S906).

The dependent recovery cost integration portion 204 adds Nmin abstract unit recovery costs AbsCost (Types: Lmin) to the IDC (Step S907).

The dependent recovery cost integration portion 204 returns the IDC as an output (Step S908).

This concludes the description of the operation of the dependent recovery cost integration portion 204 of the present example embodiment.

### (Operation of the Dependent Recovery Cost Propagation Portion 203)

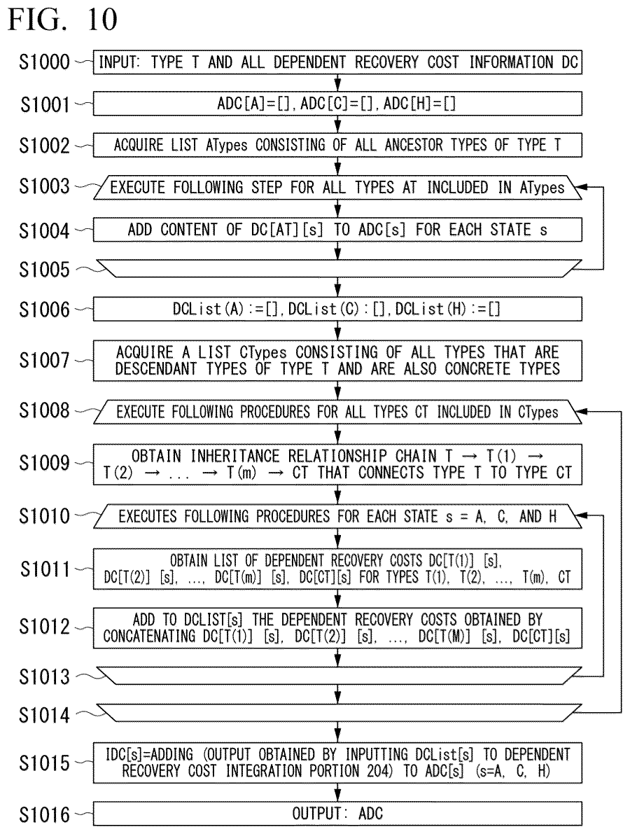

Next, the operation of the dependent recovery cost propagation portion 203 of the present example embodiment will be described. FIG. 10 is a flowchart showing the overall operation of the dependent recovery cost propagation portion 203 of the present example embodiment.

The dependent recovery cost propagation portion 203 receives the type T and all dependent recovery cost information DC as input (Step S1000).

The dependent recovery cost propagation portion 203 initializes the output dependent recovery cost information ADC with a dictionary having states A, C, and H as keys and an empty list as a value (ADC[A]=[ ], ADC[C]=[ ], ADC[H]=[ ]) (Step S1001).

The dependent recovery cost propagation portion 203 acquires a list ATypes consisting of all ancestor types of type T (Step S1002).

The dependent recovery cost propagation portion 203 executes Step S1004 for all types AT included in Atypes (Step S1003).

The dependent recovery cost propagation portion 203 adds the contents of DC[AT][s] to ADC[s] for each state s (Step S1004).

After executing step S1004 for all types AT included in Atypes, the dependent recovery cost propagation portion 203 proceeds to Step S1006 (Step S1005).

The dependent recovery cost propagation portion 203 initializes the dependent recovery cost lists DCList(A), DCList(C), and DCList(H) for the states A, C, and H, respectively, to empty lists (Step S1006).

The dependent recovery cost propagation portion 203 acquires a list CTypes consisting of all types that are descendant types of the type T and are also concrete types (Step S1007).

The dependent recovery cost propagation portion 203 executes the procedures from Step S1009 to Step S1013 for all types CT included in Ctypes (Step S1008).

The dependent recovery cost propagation portion 203 obtains the chain of inheritance relationships T→T(1)→T(2)→ . . . →T(m)→CT that connects the type T to the type CT (Step S1009). (If type inheritance is structured as a tree, then there is exactly one such chain.)

The dependent recovery cost propagation portion 203 executes the procedures from Step S1011 to Step S1012 for each state s=A, C, and H (Step S1010).

The dependent recovery cost propagation portion 203 obtains a list of dependent recovery costs DC[T(1)] [s], DC[T(2)] [s], . . . , DC[T(m)][s], DC[CT][s] for types T(1), T(2), . . . , T(m), and CT other than T included in the chain T⇒T(1)⇒T(2)⇒ . . . ⇒T(m)⇒CT obtained in Step S1009 (Step S1011).

The dependent recovery cost propagation portion 203 concatenates the list acquired in the previous step, and adds the resulting dependent recovery cost to DCList[s] (Step S1012).

The dependent recovery cost propagation portion 203 executes the procedures from Step S1011 to Step S1012 for all states s=A, C, and H, and then proceeds to Step S1014 (Step S1013).

The dependent recovery cost propagation portion 203 executes the procedures from Step S1009 to Step S1013 for all types CT included in Ctypes, and then proceeds to Step S1015 (Step S1014).

The dependent recovery cost propagation portion 203 inputs each of DCList[A], DCList[C], and DCList[H] to the dependent recovery cost integration portion 204, and adds the outputs IDC[A], IDC[C], and IDC[H] returned for each input to ADC[A], ADC[C], and ADC[H], respectively (Step S1015).

The dependent recovery cost propagation portion 203 returns the ADC as an output to the dependent recovery cost calculation procedure control portion 200 (Step S1016).

This concludes the description of the operation of the dependent recovery cost propagation portion 203 of the present example embodiment.

The above is a description of the operation of each part of the dependent recovery cost calculation portion 102 of the present example embodiment.

The overall operation will be outlined below by way of a specific example of the operation of the dependent recovery cost calculation portion 102 of the present example embodiment. As input data, the state element model shown in FIG. 26, which is composed of Target, Sub, SubA, SubB, SubC, Machine, Conn, and Host, used in a case where illustrating the dependent recovery cost, is used. Hereinafter, this input will be referred to as the state element model EXPL.

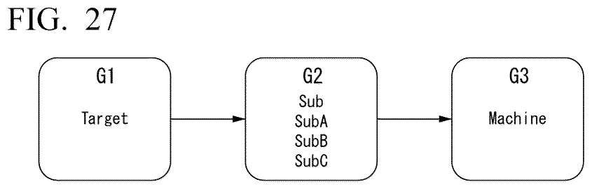

First, the dependent recovery cost calculation procedure control portion 200 divides node types into groups and creates a graph structure based on the information on the expected configuration. FIG. 27 is a graph of a type group constructed based on the state element model EXPL. Three type groups are generated: G1={Target}, G2={Sub, SubA, SubB, SubC}, and G3={Machine}, and edges are drawn from G1 to G2 and from G2 to G3. The dependent recovery cost calculation procedure control portion 200 executes the process of calculating dependent recovery costs in the order of topological sorting of this graph, that is, in the order of G3, G2, and G1.

First, the processing for G3 will be described.

Since G3 has only one type, the Machine type, and has no expected configuration, the procedure of the tangible type-dependent recovery cost construction portion 201 for the Machine type ends immediately.

Since the Machine type has neither descendant types nor ancestor types, the processing of the dependent recovery cost propagation portion 203 also ends immediately, and as a result, the dependent recovery cost of the Machine type is completely empty, that is, DC[Machine][A]=[ ], DC[Machine][C]=[ ], DC[Machine][H]=[ ].

Next, the processing for G2 will now be discussed.

Among the types included in G2, SubA, SubB, and SubC do not have expected configurations, just like the Machine type, so the procedure of the tangible type-dependent recovery cost construction portion 201 immediately ends.

An overview of the process of the tangible type-dependent recovery cost construction portion 201 for the Sub type will be described.

The tangible type-dependent recovery cost construction portion 201 calculates the provisional dependent recovery cost based on the Sub type recovery model. As a result, TDC[A]=[ ], TDC[C]=[ ], TDC[H]=[{M1:H}] is obtained.

The tangible type-dependent recovery cost construction portion 201 calculates the dependent recovery cost based on the calculated provisional dependent recovery cost. Since TDC[A] and TDC[C] are empty lists, the dependent recovery costs DC[Sub][A] and DC[Sub][C] for these are also empty. In a case where the elements of TDC[H] are converted into a list of dependent recovery costs, the result is [[Cost(Machine:H)]], and if the dependent recovery cost integration portion 204 has only one element, it outputs that element as is, resulting in DC[Sub][H]=[Cost(Machine:H)].

Since G2 includes a plurality of types having a type inheritance relationship, the processing by the dependent recovery cost propagation portion 203 is performed. The dependent recovery cost propagation portion 203 propagates information on the Sub-type dependent recovery cost to the SubA, SubB, and SubC types. As a result, for all types T in G2, the dependent recovery costs DC[T][A]=[ ], DC[T][C]=[ ], and DC[T][H]=[Cost(Machine:H)] are obtained.

Finally, the processing for G1 will be discussed.

G1 contains only one type, Target, which has two expected configurations. The tangible type-dependent recovery cost construction portion 201 calculates the provisional dependent recovery cost based on the target type recovery model. As a result, TDC[A]=[ ], TDC[C]=[ ], TDC[H]=[{S1:H}, {S1:H, S2:H}] is obtained.

The tangible type-dependent recovery cost construction portion 201 calculates the dependent recovery cost based on the calculated provisional dependent recovery cost. Since TDC[A] and TDC[C] are empty lists, the dependent recovery costs DC[Target][A] and DC[Target][C] for these are also empty. In a case where the elements of TDC[H] are converted into a list of dependent recovery costs DCList(H), the result is [[Cost(SubA:H)], [Cost(SubB:H), Cost(SubC:H)]].

The tangible type-dependent recovery cost construction portion 201 adds a dependent recovery cost derived from the corresponding type to each dependent recovery cost included in DCList(H) based on the dependent recovery cost information already calculated. Specifically, to the dependent recovery cost [Cost(SubA:H)], add the element of the dependent recovery cost DC[SubA][H]=[Cost(Machine:H)] required to transition SubA from F to H, and further to the dependent recovery cost [Cost(SubB:H),Cost(SubC:H)], add the elements of the dependent recovery cost DC[SubB][H]=[Cost(Machine:H)] required to transition SubB from F to H and the dependent recovery cost DC[SubC][H]=[Cost(Machine:H)] required to transition SubB from F to H. As a result, DCList(H)=[[Cost(SubA:H), Cost(Machine:H)],[Cost(SubB:H), Cost(SubC:H), Cost(Machine:H)]] is obtained.

The tangible type-dependent recovery cost construction portion 201 inputs DCList(H) to the dependent recovery cost integration portion 204.

The dependent recovery cost integration portion 204 integrates the input dependent recovery cost list [[Cost(SubA:H), Cost(Machine:H)], [Cost(SubB:H), Cost(SubC:H), Cost(Machine:H)]] into a single dependent recovery cost. Specifically, the dependent recovery cost integration portion 204 outputs the dependent recovery cost [Cost(Machine:H), AbsCost(SubA,SubB,SubC:3)] which includes Cost(Machine:H) included in common to both [Cost(SubA:H), Cost(Machine:H)] and [Cost(SubB:H), Cost(SubC:H), Cost(Machine:H)], and one abstract unit recovery cost AbsCost(SubA,SubB,SubC:3) which is an integration of Cost(SubA:H), Cost(SubB:H), and Cost(SubC:H).

As a result, the tangible type-dependent recovery cost construction portion 201 returns the dependent recovery costs DC[Target][A]=[ ], DC[Target][C]=[ ], DC[Target][H]=[Cost(Machine:H),AbsCost(SubA,SubB,SubC:3)] of the type Target.

Since G1 does not include any type other than Target, no processing is performed by the dependent recovery cost propagation portion 203 for G1.

Since the processing for all groups has now been completed, the dependent recovery cost calculation portion 102 outputs all dependent recovery cost information DC calculated in the above procedures as the calculation result for the input state element model EXPL.

The above is a specific example of the operation of the dependent recovery cost calculation portion 102 of the present example embodiment.

### (Operation of the Recovery Model Construction Portion 103)

Next, the operation of the recovery model construction portion 103 of the present example embodiment will be described. In the operation of the recovery model construction portion 103 of the embodiment, a “temporary state element model”, which is a special state element model (recovery state transition system), is introduced. The provisional state element model differs from a normal state element model in that it has only two states, F and H, and only two transitions, F→H and H→F, and has an “acceptance type list,” which is a list of node types, as data.

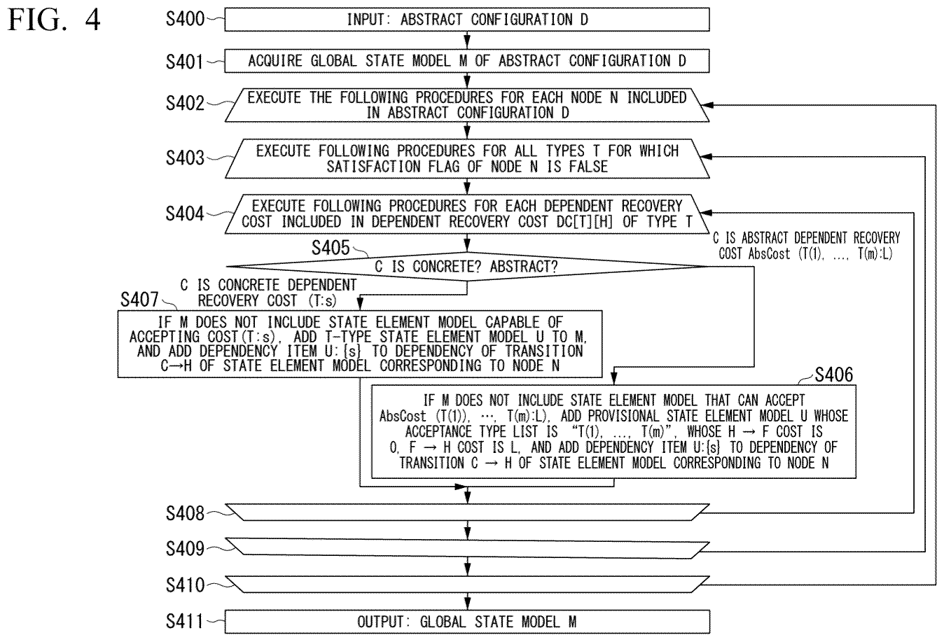

FIG. 4 is a flowchart showing the overall operation of the recovery model construction portion 103 of the present example embodiment.

The recovery model construction portion 103 receives the abstract configuration D as an input (Step S400).

The recovery model construction portion 103 acquires a global state model M of an abstract configuration D (Step S401).

(Supplement) As explained in the explanation of the embodiment of an abstract configuration, the data of the global state model of the abstract configuration is assumed to be linked to the abstract configuration.

The recovery model construction portion 103 executes the procedures from Step S403 to Step S409 for each node N included in the abstract configuration D (Step S402).

The recovery model construction portion 103 executes the procedures from Step S404 to Step S408 for all types T for which the satisfaction flag of node N is FALSE (Step S403).

The recovery model construction portion 103 executes the procedures from Step S405 to Step S407 for each unit recovery cost included in the dependent recovery cost DC[T][H] of type T (Step S404).

If the unit recovery cost selected in Step S404 is the abstract unit recovery cost AbsCost(T(1), . . . , T(m):L), the recovery model construction portion 103 proceeds to Step S406; if the unit recovery cost is the concrete unit recovery cost Cost(T:s), the recovery model construction portion 103 proceeds to Step S407 (Step S405).

If the global state model M does not include a state element model that can accept the abstract unit recovery cost AbsCost(T(1), . . . , T(m):L), the recovery model construction unit 103 adds a provisional state element model U whose acceptance type list is “T(1), . . . , T(m)”, whose transition time cost from H to F is 0, and whose transition time cost from F to H is L, and adds a dependency item “U:{H}” to the dependency of the transition C→H of the state element model corresponding to node N (Step S406).

(Supplement) A state element model that can accept an abstract unit recovery cost AbsCost(T(1), . . . , T(m):L) refers to a state element model of any type T(1), . . . , T(m), or a provisional state element model that includes at least one of T(1), . . . , T(m) in its acceptance type list.

If the global state model M does not include a state element model capable of bearing the concrete unit recovery cost Cost(T:s), the recovery model construction unit 103 adds a T-type state element model U to the global state model M, and adds a dependency item “U:{s}” to the dependency of the transition C→H of the state element model corresponding to node N (Step S407).

(Supplement) A state element model capable of assuming a concrete unit recovery cost Cost(T:s) refers to a state element model of type T, or a provisional state element model that includes type T in its acceptance type list.

After executing the procedures from Step S405 to Step S407 for all unit recovery costs included in the dependent recovery cost DC[T][H] of type T, the recovery model construction portion 103 proceeds to Step S409 (Step S408).

The recovery model construction portion 103 executes the procedures from Step S404 to Step S408 for all types T for which the satisfaction flag of node N is FALSE, and then proceeds to Step S410 (Step S409).

The recovery model construction portion 103 executes the procedures from Step S403 to Step S409 for each node N included in the abstract configuration D, and then proceeds to Step S411 (Step S410).

The recovery model construction portion 103 outputs the global state model M (Step S411).

The above is a description of the operation of the recovery model construction portion 103 in the present example embodiment.

A specific example of the output of the recovery model construction portion 103 of the present example embodiment will be described below with reference to the drawings. As the dependent recovery cost that is the premise, the total dependent recovery cost information DC calculated for the state element model EXPL shown as a specific example of the operation of the dependent recovery cost calculation portion 102 in the present example embodiment is used.

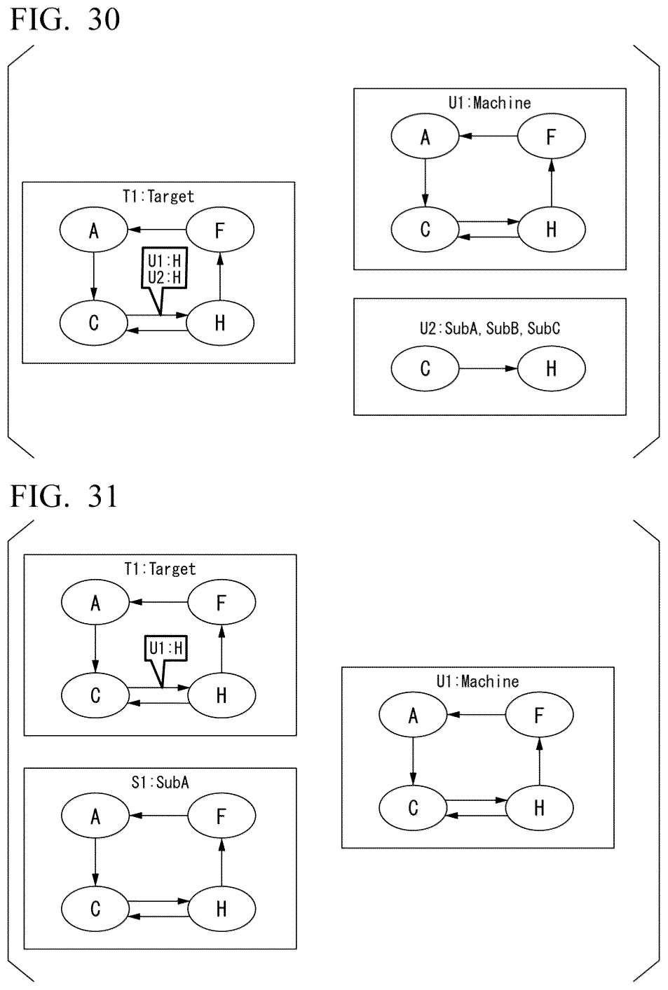

FIG. 30 shows the result obtained in a case where an abstract configuration including only one Target type node T1 is input to the recovery model construction portion 103 of the present example embodiment. Since the expected configuration is not applied to node T1, two state element models U1 and U2 are generated based on DC[Target][H]=[Cost(Machine:H), AbsCost(SubA, SubB, SubC:3)], and a dependency {U1:H, U2:H} is assigned to C→H of the recovery model of T1.

FIG. 31 shows the result obtained in a case where an abstract configuration including two nodes, a Target type node T1 and a SubA type node S1, is input to the recovery model construction portion 103 of the present example embodiment. Since the expected configuration is not applied to nodes T1 and S1, a state element model is generated based on DC[Target][H]=[Cost(Machine:H),AbsCost(SubA, SubB, SubC:3)], DC[SubA][H]=[Cost(Machine:H)]. However, unlike the global state model shown in FIG. 30, only U1, which corresponds to the Machine type state transition system, is generated in the state element model. This is because node S1 of the SubA type can tolerate the unit recovery cost AbsCost(SubA, SubB, SubC:3).

The above is an explanation of a specific example of the output of the recovery model construction portion 103 in the present example embodiment.

### (Operation of Recovery Time Requirement Verification Portion 104)

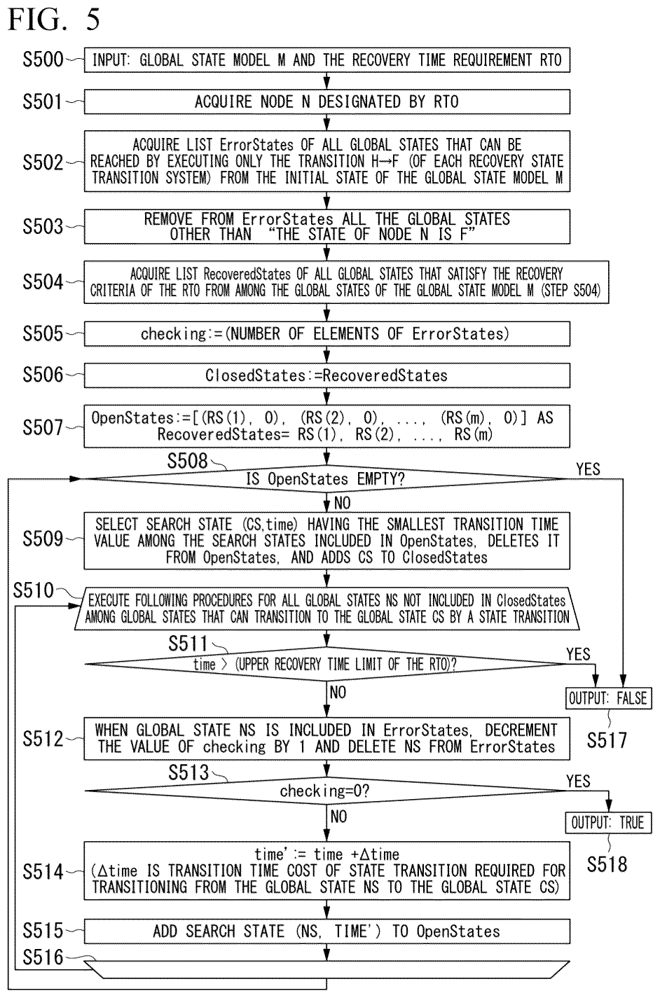

Next, the operation of the recovery time requirement verification portion 104 of the present example embodiment will be described. FIG. 5 is a flowchart showing the overall operation of the recovery time requirement verification portion 104 of the present example embodiment.

The recovery time requirement verification portion 104 receives the global state model M and the recovery time requirement RTO as input (Step S500).

The recovery time requirement verification portion 104 acquires a node N for which a recovery time requirement is specified (Step S501).

The recovery time requirement verification portion 104 acquires a list of all global states, ErrorStates, that can be reached by executing only the transition H→F (of each recovery state transition system) from the initial state of the global state model M (Step S502).

The recovery time requirement verification portion 104 removes from ErrorStates all the global states other than “the state of node Nis F” (Step S503).

The recovery time requirement verification portion 104 acquires a list RecoveredStates of all global states that satisfy the recovery criteria of the RTO from among the global states of the global state model M (Step S504).

(Supplement) The meaning of “global state NS satisfies the recovery criteria of the RTO” varies depending on the type of RTO. If the RTO is a primary recovery time requirement, it means that “the state of node N in NS is H.” If RTO is a full recovery time requirement, it means that “all states of the state model related to node N contained in NS match the initial state.”

The recovery time requirement verification portion 104 initializes an integer value checking to the number of elements of ErrorStates (Step S505).

The recovery time requirement verification portion 104 determines the list ClosedStates as [RS(1), RS(2), . . . , RS(m)] using RecoveredStates=RS(1), RS(2), . . . , RS(m) (Step S506).

The recovery time requirement verification portion 104 determines the list OpenStates as [(RS(1), 0), (RS(2), 0), . . . , (RS(m), 0)] using RecoveredStates=RS(1), RS(2), . . . , RS(m) (Step S507).

(Supplement) In the following explanation, the set included in OpenStates is called the “search state”. The integer value paired with a global state is called the “transition time”, which represents the minimum time it takes to transition from the paired global state to one of the RecoveredStates.

If OpenStates is an empty list, the recovery time requirement verification portion 104 proceeds to Step S517; otherwise, the recovery time requirement verification portion 104 proceeds to Step S509 (Step S508).

The recovery time requirement verification portion 104 selects the search state (CS, time) having the smallest transition time value among the search states included in OpenStates, deletes it from OpenStates, and adds the global state CS to ClosedStates (Step S509).

The recovery time requirement verification portion 104 executes the procedures from Step S511 to Step S515 for all global states NS that are not included in ClosedStates among global states that can transition to the global state CS by a state transition (Step S510).

(Attention) Note that in Step S510, the global states which can transition “to” the global state CS are extracted as NS, not the global states which can transition “from” the global state CS.

The recovery time requirement verification portion 104 compares the time with the upper recovery time limit of the RTO, and if the time is greater, the process proceeds to Step S517, otherwise the process proceeds to Step S512 (Step S511).

In a case where the global state NS is included in ErrorStates, the recovery time requirement verification portion 104 decrements the value of checking by 1 and deletes NS from ErrorStates (Step S512).

If checking becomes 0, the recovery time requirement verification portion 104 proceeds to Step S518, otherwise, the recovery time requirement verification portion 104 proceeds to Step S514 (Step S513).

The recovery time requirement verification unit 104 determines that the transition time cost of the state transition required for transitioning from the global state NS to the global state CS is Δtime, and determines time′:=time+Δtime (Step S514).

The recovery time requirement verification portion 104 adds the search state (NS, time′) to OpenStates (Step S515).

(Supplement) In a case where adding the search state (NS, time′) to OpenStates in Step S515, if there is a state whose “global state is NS” and whose “transition time is equal to or greater than time”, it may be removed from OpenStates.

The recovery time requirement verification portion 104 executes the procedures from Step S511 to Step S515 for all global states NS that can transition to the global state CS by a state transition, and then returns to Step S508 (Step S516).

The recovery time requirement verification portion 104 outputs FALSE and ends the operation (Step S517).

The recovery time requirement verification portion 104 outputs TRUE and ends the operation (Step S518).

The above is a description of the operation of the recovery time requirement verification portion 104 in the present example embodiment.

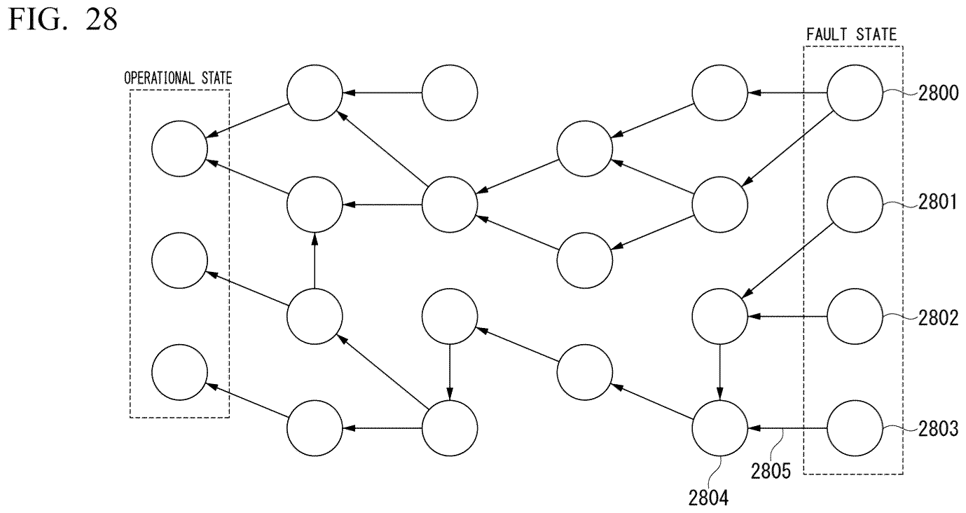

A specific example of the operation of the recovery time requirement verification portion 104 of the present example embodiment will be described with reference to the drawings. FIG. 28 is an image diagram of a state transition system consisting of global states and transitions between them. The circles correspond to global states, and the global states can transition along the arrows between them. For simplicity, the specific representation of each global state is omitted, and for simplicity of the following explanation, the transition time cost for all transitions is unified to 1.

FIG. 28 also shows an “operational state” that satisfies the recovery criteria of the RTO, and a “failure state” that corresponds to ErrorStates obtained in steps S502 and S503.

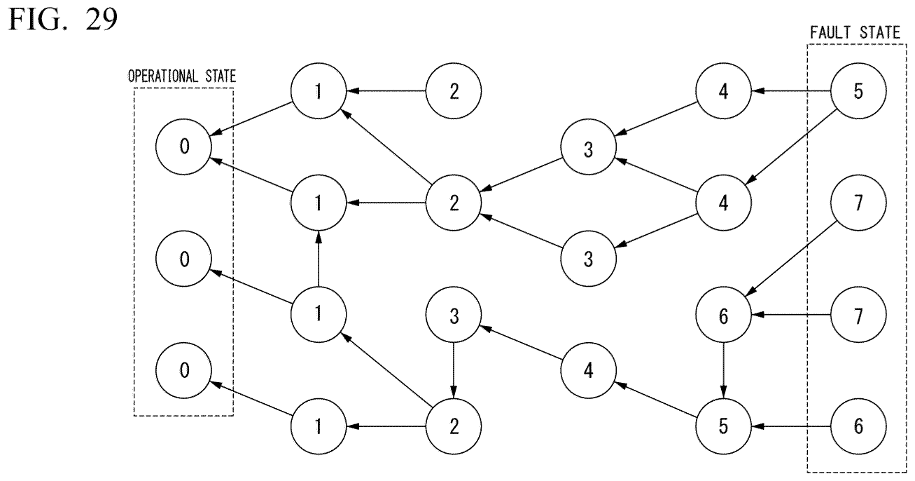

The procedure of Step S508 and thereafter of the recovery time requirement verification portion 104 intuitively corresponds to a process of starting from the operational state, scanning the graph in FIG. 28 in the opposite direction to the arrow, and determining the shortest transition time cost required to reach any of the recovery states from each global state. FIG. 29 shows the transition time costs required to reach any of the operational states from each global state, which are obtained by such processing, for the nodes in FIG. 28.

Each case in which the recovery time requirement verification portion 104 returns an output will be described with reference to FIG. 28 and FIG. 29.

(Case 1: Case where checking becomes 0 in Step S513) Checking is initially initialized to the number of failure states, and is decremented by 1 in a case where a new failure state is selected in Step S508 and the transition time is within the upper limit of the recovery time of the RTO. For example, if the upper recovery time limit is 10 and the input is the data in FIG. 28, checking is initialized to 4, and then the value of checking becomes 0 during graph traversal in a case where all of the failure states are discovered in the following order: global state 2800 (transition time 5), global state 2803 (transition time 6), global state 2801 (transition time 7), and global state 2802 (transition time 7). In this way, the fact that the checking value has reached 0 means that it has been confirmed that it is possible to reach an operational state from any failure state within the transition time limit of the RTO recovery time, and therefore it has been verified that the RTO has been met.

(Case 2: Case where time exceeds the upper limit of the RTO recovery time in Step S511) This is a case where it is detected that the operational state cannot be reached within the upper limit of the RTO recovery time. For example, if the upper limit of the RTO recovery time is 5, this case will be met in a case where global state 2803 or 2804 is selected in Step S508. What this means is that “because checking is not 0, there is a failure state that has not yet been reached” and “all states to be reached in the future will have a ‘shortest transition time to reach an operational state’ of 6 or more.” This means that there are failure states that cannot be recovered from without taking more than six transition times, which will definitely violate the RTO.

(Case 3: OpenStates is empty in step S508) This case applies in a case where there is an unreachable failure state. There are no such failure states in FIG. 28, but if we consider a model in which, for example, transition 2805 is not possible, then global state 2803 is unreachable. In such a case, the procedure continues without falling into either case 1 or 2, and eventually all states have been scanned and the case falls into case 3. In other words, case 3 means there is an “unrecoverable” failure state, which will definitely violate the RTO.

The above is an explanation of a specific example of the operation of the recovery time requirement verification portion 104 of the present example embodiment.

### (Operation of Configuration Embodiment Portion 101)

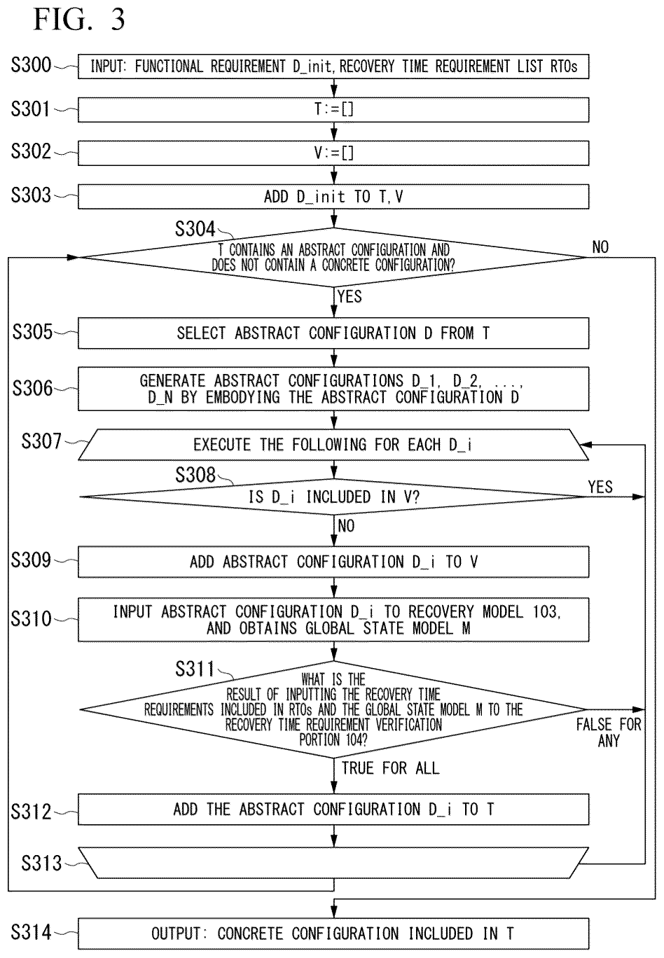

Next, the operation of the configuration embodiment portion 101 of the present example embodiment for designing an ICT system will be described with reference to the drawings. The configuration embodiment portion 101 of the present example embodiment is basically the same as the configuration instantiation procedure described in Patent Document 1, but differs in that it also receives recovery time requirements as input and includes a step of verifying the recovery time requirements for the abstract configuration in the process of being embodied by the recovery model construction portion 103 and the recovery time requirement verification portion 104. It is assumed that, prior to the processing described next with reference to FIG. 3, the dependent recovery cost calculation portion 102 has already calculated all dependent recovery cost information DC by the processing described above with reference to FIGS. 6 to 10.

FIG. 3 is a flowchart showing a procedure in which the configuration embodiment portion 101 of the present example embodiment derives a concrete configuration of the system.

The configuration embodiment portion 101 receives as input from an input/output device the configuration requirement D_init expressed in the form of an abstract configuration and a list RTOs of recovery time requirements (Step S300).

The configuration embodiment portion 101 initializes the search candidate list T to an empty list (Step S301).

The configuration embodiment portion 101 initializes the searched configuration list V to an empty list (Step S302).

The configuration embodiment portion 101 adds D_init to T and V (Step S303).

If the search candidate list T contains an abstract configuration and does not contain a concrete configuration, the configuration embodiment portion 101 proceeds to Step S305, and otherwise proceeds to Step S314 (Step S304).

The configuration embodiment portion 101 selects one abstract configuration D included in T (Step S305).

The configuration embodiment portion 101 generates abstract configurations D_1, D_2, . . . , D_N by embodying the abstract configuration D selected in Step S305 (Step S306).

(Supplement) As a specific method for the configuration embodiment portion 101 of the present example embodiment to embody an abstract configuration, for example, the method described in Non-Patent Document 1 can be used. However, in the present example embodiment, the specific embodying method is not limited to a specific technique.

(Supplement 2) However, the embodiment of the present example embodiment must satisfy the following properties (1) and (2). (The method described in Non-Patent Document 1 satisfies these requirements.) (1) A node once created is not deleted by embodiment. (2) A specific edge once created cannot be deleted by embodiment.

The configuration embodiment portion 101 executes the procedures from Step S310 to Step S312 for each abstract configuration D_i generated in the previous step (Step S307).

If D_i is included in the searched configuration list V, the configuration embodiment portion 101 returns to Step S307, and if not, proceeds to Step S309 (Step S308).

The configuration embodiment portion 101 adds D_i to the searched configuration list V (Step S309).

The configuration embodiment portion 101 inputs the abstract configuration D_i to the recovery model construction portion 103, and obtains the global state model M as the output (Step S310).

The configuration embodiment portion 101 inputs all the recovery time requirements included in the RTOs and the global state model M to the recovery time requirement verification portion 104 and verifies the output. If any one of them outputs FALSE, the process returns to Step S307. If TRUE is output for all the items, the process proceeds to Step S312 (Step S311).

The configuration embodiment portion 101 adds the abstract configuration D_i to T (Step S312).

The configuration embodiment portion 101 executes the procedures from Step S310 to Step S312 for all the abstract configurations D_i generated in Step S306, and then returns to Step S304 (Step S313).

The configuration embodiment portion 101 outputs the concrete configuration D_out included in the search candidate list T to the input/output device as the result of the system configuration derivation device 100. If the concrete configuration is not included in the search candidate list T, it gives notice that the search failed (Step S314).

The above is the explanation of the operation of configuration embodiment portion 101.

### (Effect)

The dependent recovery cost calculation portion 102 of the present example embodiment estimates in advance the minimum operations required for failure recovery of each component and the associated time cost, based on information about the component model used by the configuration embodiment portion 101 to embody the abstract configuration.

Moreover, the recovery time requirement verification portion 104 of the present example embodiment receives the abstract configuration and the recovery time requirement, and estimates an approximation of the recovery time for the abstract configuration in the process of being embodied based on the recovery cost information estimated by the dependent recovery cost calculation portion 102, and verifies that the abstract configuration satisfies the recovery time requirement.

In addition, the configuration concretization unit 101 of the system configuration derivation device 100 of the present example embodiment receives the configuration requirements and the recovery time requirements, and by repeatedly embodying the configuration requirements, performs a tree search on a tree structure with the abstract configurations as nodes, and also verifies, by the recovery time requirement verification portion 104, the recovery time requirements for the abstract configurations generated in the process, and by eliminating abstract configurations that do not satisfy the recovery time requirements, finally outputs configuration information of an ICT system that is completely embodied and satisfies the recovery time requirements.

Therefore, since the system configuration derivation device 100 of the present example embodiment can perform automatic design for a given functional requirement by repeating only the embodying operations whose results can satisfy a given recovery time requirement, it can efficiently find a concrete configuration that simultaneously satisfies both the given functional requirement and the recovery time requirement.

### Second Example Embodiment

Hereinbelow, a system configuration derivation device 1100 according to the second example embodiment will be described with reference to the drawings.

### (Composition)

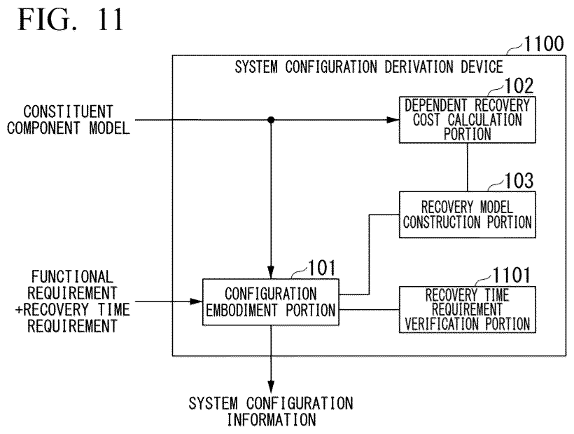

FIG. 11 is a second block diagram showing an example of the configuration of the system configuration derivation device 1100. The system configuration derivation device 1100 is provided with a recovery time requirement verification portion 1101 instead of the recovery time requirement verification portion 104 of the system configuration derivation device 100, but the other constituent elements are exactly the same as those of the system configuration derivation device 100.

The recovery time requirement verification portion 1101 has the same input/output format as the recovery time requirement verification portion 104, but differs in that the “recovery time” used to determine whether or not the upper recovery time limit is violated is not the sum of the execution times of all state transitions included in the recovery procedure, but the execution time in a case where all state transitions included in the recovery procedure are executed in parallel to the maximum extent possible (hereinafter referred to as “parallel execution time”).

The “parallel execution time” of the recovery procedure will be explained below using a concrete example.

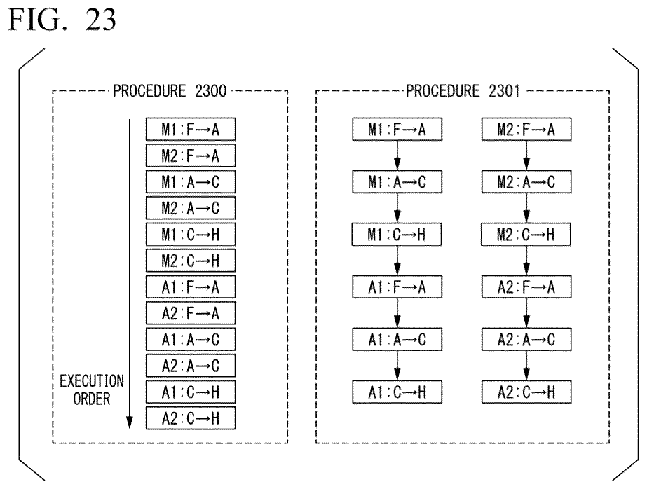

FIG. 23 illustrates an example of a recovery procedure for recovering two applications A1, A2 and the machines M1, M2 that host them in two different ways (procedures 2300, 2301). Each contains 12 state transitions: “M1:F→A”, “M2:F→A”, “M1:A→C”, “M2:A→C”, “M1:C→H”, “M2:C→H”, “A1:F→A”, “A2:F→A”, “A1:A→C”, “A2:A→C”, “A1:C→H”, and “A2:C→H”.

Procedure 2300 lists state transitions (hereinafter referred to as “recovery tasks”) that need to be executed for recovery in order of execution, and the system can be completely restored by executing the tasks in order from the top. It can be said that the recovery time requirement verification portion 104 verifies whether the time required for such “sequential execution” satisfies the specified recovery time requirement.

On the other hand, a procedure 2301 indicates, with arrows, the minimum “execution sequence” required between recovery tasks. Specifically, the following orders are specified: “M1:F→A”→“M1:A→C”→“M1:C→H”→“A1:F→A”→“A1:A→C”→“A1:C→H” and “M2:F→A”→“M2:A→C”→“M2:C→H”→“A2:F→A”→“A2:A→C”→“A2:C→H”. A graph consisting of such recovery tasks and their execution order is called a “recovery task model”, and in a case where task B can be executed after task A (task A→task B), task B is said to depend on task A.

The above-mentioned “required order between recovery tasks” means that the tasks can be executed while satisfying dependencies on the corresponding state models. For example, ordering relationships such as “M1:F→A”→“M1:A→C”→“M1:C→H” or “A1:F→A”→“A1:A→C”→“A1:C→H” are required because the path from F to H in the state model is F→A→C→H. On the other hand, an ordering relationship such as “M1:C→H”→“A1:F→A” is required by the dependency [{M1:[H]}] defined on the transition F→A of A1.

The recovery task model can be executed in parallel as follows. That is, if all dependent tasks among the recovery tasks included in the recovery task model have been executed, the recovery task is executed.

Step 2301 can theoretically be completed in half the time it takes Step 2300 through parallel execution.

As described above, the minimum time required in a case where the recovery task models of a recovery procedure are executed in parallel is called the “parallel execution time.” In a case where considering an environment in which system recovery is performed completely in parallel, it may be considered that the recovery time requirement should be based on the parallel execution time.

This concludes the explanation of “parallel execution time.”

### (Operation)

The operation of the recovery time requirement verification portion 1101 of the present example embodiment will be described.

FIG. 12 is a flowchart showing the overall operation of the recovery time requirement verification portion 1101 in the present example embodiment. The operation of the recovery time requirement verification portion 1101 in the present example embodiment is almost the same as the operation of the recovery time requirement verification portion 104, and only the five steps indicated by double lines in FIG. 12 are different. Specifically, Step S1200 is executed instead of Step S507, Step S1201 is executed instead of Step S509, Step S1202 is executed instead of Step S511, Step S1203 is executed instead of Step S514, and Step S1204 is executed instead of Step S515.

The recovery time requirement verification portion 1101 determines the list OpenStates as [(RS(1), φ), (RS(2), φ), . . . , (RS(m), φ)] using RecoveredStates=RS(1), RS(2), . . . , RS(m) (Step S1200).

(Supplement) Here, φ is an empty task model.

The recovery time requirement verification portion 1101 selects the search state (CS, TM) having the smallest parallel execution time value of the task model from among the search states included in OpenStates, deletes it from OpenStates, and adds the global state CS to ClosedStates (Step S1201).

The recovery time requirement verification portion 1101 compares the TM parallel execution time with the RTO recovery time upper limit, and if the TM parallel execution time is greater, proceeds to Step S517, otherwise proceeds to Step S512 (Step S1202).

The recovery time requirement verification portion 1101 adds state transitions required for transition from the global state NS to the global state CS to the task model TM, and configures the task model TM′ (Step S1203).

The recovery time requirement verification portion 1101 adds the search states (NS, TM′) to OpenStates (Step S1204).

The above is a description of the operation of the recovery time requirement verification portion 1101 in the present example embodiment.

### (Effect)

The recovery time requirement verification portion 1101 of the present example embodiment differs from the recovery time requirement verification portion 104 in that it determines whether a recovery time requirement is satisfied or not based on the parallel execution time.

Therefore, the system configuration derivation device 1100 of the present example embodiment can output a concrete configuration that satisfies both given functional requirements and recovery time requirements in an environment where system failure recovery operations are performed in parallel.

(Supplement) Note that the total execution time of the recovery tasks will always be equal to or longer than the parallel execution time, and therefore the recovery time requirement will be “tighter” than if the parallel execution time was the basis. That is, even if a configuration can be output by the system configuration derivation device 1100 of the present example embodiment, the system configuration derivation device 100 of the first example embodiment may not output the configuration because it violates the recovery time requirement.

### Other Example Embodiments

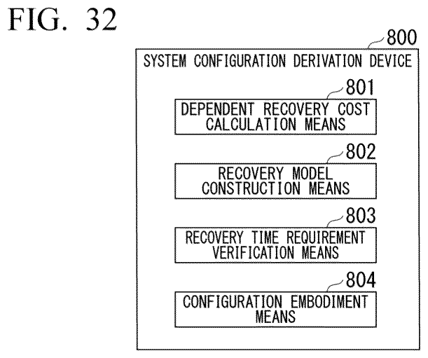

FIG. 32 is a third block diagram showing an example of the configuration of the system configuration derivation device.

The system configuration derivation device 800 is provided with a dependent recovery cost calculation means 801, a recovery model construction means 802, a recovery time requirement verification means 803, and a configuration embodiment means 804.

The expected configuration is a peripheral structure necessary for a system component to operate normally, the recovery model is model data that represents the relationship between the failure recovery operation of the system component and the peripheral structures, the component model is model data that manages the expected configuration and the recovery model of various abstract or concrete system components, the abstract configuration represents the configuration of the system including undetermined parts by a graph-like structure composed of nodes corresponding to components and edges that represent the relationships between the components, and the concretization is a transformation of the graph structure that determines the undetermined parts of the abstract configuration based on the information of the expected configuration, in a case where the dependent recovery cost calculation means 801 receives the component model as an input and calculates the recovery cost required for recovering the structure derived from the expected configuration of the entity having the component model as its type based on the information of the recovery model and the expected configuration defined in association with the component model. The recovery model construction means 802 receives the abstract configuration and the recovery cost as input, and constructs a global state model that indicates an operation model related to failure recovery of the abstract configuration. The restoration time requirement verification means 803 receives the global state model and the restoration time requirement as input, and verifies whether the global state model satisfies the restoration time requirement. The configuration concretization means 804 receives functional requirements and the recovery time requirements as input, generates abstract configurations that concretize the functional requirements using a mechanism for gradually concretizing abstract configurations as candidates for possible system configurations, inputs the generated abstract configurations to the construction means to obtain the global state model, and inputs the global state model and the recovery time requirements to the verification means to eliminate the candidates that do not satisfy the recovery time requirements, thereby deriving a system configuration that simultaneously satisfies both the functional requirements and the recovery time requirements.

Note that a part of the system configuration derivation devices 100, 1100, and 800 in the above-described example embodiments may be realized by a computer. In this case, the function may be realized by recording a program for realizing the function on a computer-readable recording medium, and reading and executing the program recorded on the recording medium into a computer system. The “computer system” referred to here is a computer system built into the system configuration derivation device 100, 1100, 800, and includes hardware such as an OS (Operating System) and peripheral devices.

In addition, the term “computer-readable recording medium” refers to portable media such as flexible disks, optical magnetic disks, ROMs, and CD-ROMs, as well as storage devices such as hard disks built into computer systems. Furthermore, the term “computer-readable recording medium” may also include something that dynamically holds a program for a short period of time, such as a communication line in a case where transmitting a program via a network such as the Internet or a communication line such as a telephone line, or something that holds a program for a certain period of time, such as volatile memory inside a computer system that is the server or client in that case. Furthermore, the above program may be for realizing some of the functions described above, and may further be capable of realizing the functions described above in combination with a program already recorded in the computer system.

Furthermore, a part or the whole of the system configuration derivation devices 100, 1100, 800 in the above-described example embodiments may be realized as an integrated circuit such as an LSI (Large Scale Integration). Each processing unit of the system configuration derivation devices 100, 1100, and 800 may be implemented as a separate processor, or a part or all of the units may be integrated into a processor. Furthermore, the method of integration is not limited to LSI, but may be a dedicated circuit or a general-purpose processor. Furthermore, if an integrated circuit technology that can replace LSIs emerges due to advances in semiconductor technology, an integrated circuit based on that technology may be used.

While preferred example embodiments of the present disclosure have been described and illustrated in detail above with reference to the drawings, it should be understood that these are exemplary of the disclosure and are not to be considered as limiting. Additions, omissions, substitutions, and other modifications can be made without departing from the scope of the present disclosure. Accordingly, the disclosure is not to be considered as being limited by the foregoing description, and is only limited by the scope of the appended claims.. In addition, one aspect of the present disclosure may be modified in various ways within the scope of the claims, and example embodiments obtained by appropriately combining the technical means disclosed in different example embodiments are also included in the technical scope of the present disclosure. Furthermore, the present disclosure also includes configurations in which elements described in the above example embodiments and modified examples are replaced with elements that produce similar effects. Moreover, each example embodiment can be appropriately combined with other example embodiments.

Some or all of the above-described example embodiments can be described as, but are not limited to, the following supplementary notes. In addition, the disclosure of the supplementary notes corresponding to the dependent claims regarding the system configuration derivation device may also be made dependent on the system configuration derivation method and program.

### (Supplementary Note 1)

A system configuration derivation device comprising: a means that, with a constituent component model as input, calculates a recovery cost required for recovery of a structure derived from an expected configuration of an entity having a type indicated by the component model, based on information on a recovery model defined in association with the component model and the expected configuration, in a case where embodiment refers to the transformation of a graph structure that determines the undecided parts of an abstract configuration based on the information of the expected structure, wherein the expected configuration is a peripheral structure necessary for system components to operate normally; the recovery model is model data that represents the relationship between failure recovery operations of system components and peripheral structures; the constituent component model is model data that defines type-specific information including the expected configuration and the recovery model of various abstract or concrete system components; the abstract configuration is a representation of the configuration of a system that includes undetermined parts, using a graph-like structure consisting of nodes that correspond to components and edges that indicate relationships between the components; and that which includes the nodes and edges is collectively called an entity, while the type of the entity is called a type; a means that, with an abstract configuration and recovery cost as input, constructs a global state model representing an operation model relating to failure recovery of the abstract configuration; a means that, with the global state model and the recovery time requirement as input, verifies whether the global state model satisfies the recovery time requirement; and a means that, with a functional requirement and the recovery time requirement as input, generates an abstract configuration that embodies the functional requirement using a mechanism for gradually embodying the abstract configuration as a possible system configuration candidate, inputs the generated abstract configuration to the construction means to obtain the global state model, and inputs the global state model and the recovery time requirement to the verification means to eliminate the candidates that do not satisfy the recovery time requirement, thereby deriving a system configuration that simultaneously satisfies the functional requirement and the recovery time requirement.

### (Supplementary Note 2)

The system configuration derivation device according to Supplementary Note 1, wherein the cost output means extracts, from the expected configuration of each node and type inheritance relationship information, constituent components that are required as a minimum for a system component corresponding to the node type to operate normally, and calculates the cost as a list of restoration operations related to peripheral components that are required as a minimum for the restoration of the constituent elements.

### (Supplementary Note 3)

The system configuration derivation device according to Supplementary Note 1 or 2, wherein the verifying means, based on the input global state model, lists states in which the system can operate normally and failure states in which a fault has occurred in the system, and then, starting from a state in which the system can operate on the global state model, scans the global state model in a direction opposite to the state transition of the system, thereby verifying the input recovery time requirement by examining the length of the shortest path from each of the failure states to an operational state.

### (Supplementary Note 4)

A system configuration derivation method comprising: calculating, with a constituent component model as input, a recovery cost required for recovery of a structure derived from an expected configuration of an entity having a type indicated by the component model, based on information on a recovery model defined in association with the component model and the expected configuration, in a case where embodiment refers to the transformation of a graph structure that determines the undecided parts of an abstract configuration based on the information of the expected structure, wherein the expected configuration is a peripheral structure necessary for system components to operate normally; the recovery model is model data that represents the relationship between failure recovery operations of system components and peripheral structures; the constituent component model is model data that defines type-specific information including the expected configuration and the recovery model of various abstract or concrete system components; the abstract configuration is a representation of the configuration of a system that includes undetermined parts, using a graph-like structure consisting of nodes that correspond to components and edges that indicate relationships between the components; and that which includes the nodes and edges is collectively called an entity, while the type of the entity is called a type; generating, with a functional requirement and a recovery time requirement as input, an abstract configuration that embodies the functional requirement using a mechanism for gradually embodying the abstract configuration as a possible system configuration candidate; constructing, with the generated abstract configuration and the recovery cost as input, a global state model representing an operation model relating to failure recovery of the abstract configuration; verifying, with the global state model and the recovery time requirement as input, whether the global state model satisfies the recovery time requirement; and deriving a system configuration that simultaneously satisfies the functional requirement and the recovery time requirement by eliminating the candidates that do not satisfy the recovery time requirement.

### (Supplementary Note 5)

A program that causes a computer to execute the processes of: calculating, with a constituent component model as input, a recovery cost required for recovery of a structure derived from an expected configuration of an entity having a type indicated by the component model, based on information on a recovery model defined in association with the component model and the expected configuration, in a case where embodiment refers to the transformation of a graph structure that determines the undecided parts of an abstract configuration based on the information of the expected structure, wherein the expected configuration is a peripheral structure necessary for system components to operate normally; the recovery model is model data that represents the relationship between failure recovery operations of system components and peripheral structures; the constituent component model is model data that defines type-specific information including the expected configuration and the recovery model of various abstract or concrete system components; the abstract configuration is a representation of the configuration of a system that includes undetermined parts, using a graph-like structure consisting of nodes that correspond to components and edges that indicate relationships between the components; and that which includes the nodes and edges is collectively called an entity, while the type of the entity is called a type; generating, with a functional requirement and a recovery time requirement as input, an abstract configuration that embodies the functional requirement using a mechanism for gradually embodying the abstract configuration as a possible system configuration candidate; constructing, with the generated abstract configuration and the recovery cost as input, a global state model representing an operation model relating to failure recovery of the abstract configuration; verifying, with the global state model and the recovery time requirement as input, whether the global state model satisfies the recovery time requirement; and deriving a system configuration that simultaneously satisfies the functional requirement and the recovery time requirement by eliminating the candidates that do not satisfy the recovery time requirement.

What is claimed is:

1. A system configuration derivation device comprising:
at least one memory configured to store instructions; and
at least one processor configured to execute the instructions to:
calculate, with a constituent component model as input, a recovery cost required for recovery of a structure derived from an expected configuration of an entity having a type indicated by the constituent component model, based on information on a recovery model defined in association with the constituent component model and the expected configuration, in a case where embodiment refers to a transformation of a graph structure that determines undecided parts of an abstract configuration based on information of the expected configuration, wherein the expected configuration is a peripheral structure necessary for system components to operate normally; the recovery model is model data that represents a relationship between failure recovery operations of the system components and the peripheral structures; the constituent component model is model data that defines type-specific information including the expected configuration and the recovery model of various abstract or concrete system components; the abstract configuration is a representation of a configuration of a system that includes undetermined parts, using a graph-like structure including nodes that correspond to components and edges that indicate relationships between the components; the entity includes the nodes and edges;
construct, with the abstract configuration and the recovery cost as input, a global state model representing an operation model relating to failure recovery of the abstract configuration;
verify, with the global state model and a recovery time requirement as input, whether the global state model satisfies the recovery time requirement; and
generate, with a functional requirement and the recovery time requirement as input, the abstract configuration that embodies the functional requirement using a mechanism for gradually embodying the abstract configuration as a possible system configuration candidate, inputs the generated abstract configuration to the constructing to obtain the global state model, and inputs the global state model and the recovery time requirement to the verifying to eliminate candidates that do not satisfy the recovery time requirement, thereby deriving a system configuration that simultaneously satisfies the functional requirement and the recovery time requirement.

2. The system configuration derivation device according to claim 1,
wherein the at least one processor is configured to execute the instructions to extract, from the expected configuration of each node type and type inheritance relationship information, constituent components that are required as a minimum for a system component corresponding to the node type to operate normally, and calculate the recovery cost as a list of restoration operations related to peripheral components that are required as a minimum for the restoration of the constituent components.

3. The system configuration derivation device according to claim 1,
wherein the at least one processor is configured to execute the instructions to list, based on the input global state model, states in which the system can operate normally and failure states in which a fault has occurred in the system, and then, starting from a state in which the system can operate on the global state model, scan the global state model in a direction opposite to the state transition of the system, thereby verifying the input recovery time requirement by examining a length of a shortest path from each of the failure states to an operational state.

4. The system configuration derivation device according to claim 2,
wherein the at least one processor is configured to execute the instructions to list, based on the input global state model, states in which the system can operate normally and failure states in which a fault has occurred in the system, and then, starting from a state in which the system can operate on the global state model, scan the global state model in a direction opposite to the state transition of the system, thereby verifying the input recovery time requirement by examining a length of a shortest path from each of the failure states to an operational state.

5. A system configuration derivation method comprising:
calculating, with a constituent component model as input, a recovery cost required for recovery of a structure derived from an expected configuration of an entity having a type indicated by the constituent component model, based on information on a recovery model defined in association with the constituent component model and the expected configuration, in a case where embodiment refers to a transformation of a graph structure that determines undecided parts of an abstract configuration based on information of the expected configuration, wherein the expected configuration is a peripheral structure necessary for system components to operate normally; the recovery model is model data that represents a relationship between failure recovery operations of the system components and the peripheral structures; the constituent component model is model data that defines type-specific information including the expected configuration and the recovery model of various abstract or concrete system components; the abstract configuration is a representation of a configuration of a system that includes undetermined parts, using a graph-like structure including nodes that correspond to components and edges that indicate relationships between the components; the entity includes the nodes and edges;
generating, with a functional requirement and a recovery time requirement as input, the abstract configuration that embodies the functional requirement using a mechanism for gradually embodying the abstract configuration as a possible system configuration candidate;
constructing, with the generated abstract configuration and the recovery cost as input, a global state model representing an operation model relating to failure recovery of the abstract configuration;
verifying, with the global state model and the recovery time requirement as input, whether the global state model satisfies the recovery time requirement; and
deriving a system configuration that simultaneously satisfies the functional requirement and the recovery time requirement by eliminating the candidates that do not satisfy the recovery time requirement.

6. A non-transitory storage medium storing a program that causes a computer to execute the processes of:
calculating, with a constituent component model as input, a recovery cost required for recovery of a structure derived from an expected configuration of an entity having a type indicated by the constituent component model, based on information on a recovery model defined in association with the constituent component model and the expected configuration, in a case where embodiment refers to a transformation of a graph structure that determines undecided parts of an abstract configuration based on information of the expected configuration, wherein the expected configuration is a peripheral structure necessary for system components to operate normally; the recovery model is model data that represents a relationship between failure recovery operations of the system components and the peripheral structures; the constituent component model is model data that defines type-specific information including the expected configuration and the recovery model of various abstract or concrete system components; the abstract configuration is a representation of a configuration of a system that includes undetermined parts, using a graph-like structure including nodes that correspond to components and edges that indicate relationships between the components; the entity includes the nodes and edges;
generating, with a functional requirement and a recovery time requirement as input, the abstract configuration that embodies the functional requirement using a mechanism for gradually embodying the abstract configuration as a possible system configuration candidate;
constructing, with the generated abstract configuration and the recovery cost as input, a global state model representing an operation model relating to failure recovery of the abstract configuration;
verifying, with the global state model and the recovery time requirement as input, whether the global state model satisfies the recovery time requirement; and
deriving a system configuration that simultaneously satisfies the functional requirement and the recovery time requirement by eliminating the candidates that do not satisfy the recovery time requirement.
